(19) United States
(12) Patent Application Publication
(10) Pub. No.: US 2025/0218973 A1
(43) Pub. Date: Jul. 3, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Fu-Hai LI, Tainan City (TW); Chien Hung LIU, Hsinchu County (TW); Kuo-Ching HUANG, Hsinchu City (TW)

(21) Appl. No.: 18/398,925

(22) Filed: Dec. 28, 2023

(51) Int. Cl. H01L 23/552; H01L 23/00; H01L 23/498; H01L 23/66; H01L 25/00; H01L 25/065

(52) U.S. Cl. CPC H01L 23/552; H01L 23/49822; H01L 23/66; H01L 24/08; H01L 25/0657; H01L 25/50; H01L 2223/6677; H01L 2224/08145; H01L 2225/06537; H01L 2924/3025

(57) ABSTRACT

A semiconductor device includes a radio frequency (RF) switch and a shielding layer between the RF switch and a semiconductor substrate of the semiconductor device. The shielding layer suppresses electric field emissions and/or magnetic field emissions generated by the RF switch, which prevents, minimizes, and/or otherwise reduces the likelihood of the electric field emissions and/or the magnetic field emissions causing a parasitic current to be induced in the semiconductor substrate. In this way, the shielding layer described herein reduces, minimizes, and/or prevents harmonic distortion in the operation of the RF switch. This enables the RF switch to maintain linear operation, which enables more accurate and faster switching for the RF circuit.

### BACKGROUND

A wireless communication device may include a radio frequency (RF) front-end device that includes one or more RF circuits fabricated to implement one or more functionalities of the RF front-end device. Examples of such RF circuits include filters, tuners, multiplexers, low noise amplifiers, and/or RF switches, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2C are diagrams of an example radio frequency (RF) switch described herein.

FIGS. 3A-3C are diagrams of example implementations of the operation of the RF switch described herein.

FIGS. 4A-4C are diagrams of example implementations of an example semiconductor device described herein.

FIGS. 5A and 5B are diagrams of examples of electric field emissions and magnetic field emissions without and with the shielding layer described herein.

FIGS. 6A-6F are diagrams of an example implementation of forming a semiconductor device described herein.

FIGS. 7A-7J are diagrams of an example implementation of forming the RF switch described herein.

FIGS. 8A-8C are diagrams of example implementations of a semiconductor device described herein.

FIG. 9 is a diagram of example components of a device described herein.

FIG. 10 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some circuits included in a radio frequency (RF) front-end device may be susceptible to interference referred to as electromagnetic interference (EMI). EMI is a prevalent type of RF interference that affects electronic circuitry by electromagnetic induction, electromagnetic coupling, and/or conduction, among other examples. EMI may cause a parasitic current to be induced in a semiconductor substrate of an RF front-end device, which may cause harmonic distortion in the operation of one or more circuits of the RF front-end device. For example, an RF switch is a type of circuit in an RF front-end device that operates at high frequencies (e.g., in the gigahertz (GHz) range or greater). The high frequencies at which the RF switch operates may result in EMI emissions in the form of electric field (E-field) emissions and/or magnetic field (H-field) emissions that propagate from the RF switch to the underlying semiconductor substrate. The E-field emissions and/or the H-field emissions may induce a parasitic current in the semiconductor substrate, which may result in harmonic distortion in the RF switch. The harmonic distortion may affect the operation of the RF switch in that the harmonic distortion may cause the operation of the RF switch to become nonlinear. Nonlinear operation of the RF switch may result in distorted output signals from the RF switch, which may cause errors in the output signal and/or may cause data encoded in the output signals to become corrupted.

In some implementations described herein, a semiconductor device such as an RF front-end device includes an RF circuit such as an RF switch. A shielding layer is included between the RF switch and the semiconductor substrate of the semiconductor device. The shielding layer suppresses E-field emissions and/or H-field emissions generated by the RF switch, which prevents, minimizes, and/or otherwise reduces the likelihood of the E-field emissions and/or the H-field emissions causing a parasitic current to be induced in the semiconductor substrate.

In this way, the shielding layer described herein reduces, minimizes, and/or prevents harmonic distortion in the operation of the RF switch. This enables the RF switch to maintain linear operation, which enables more accurate and faster switching for the RF circuit (e.g., relative to if the shielding layer were omitted from the semiconductor device). The more accurate and faster switching of the RF switch reduces the error rate and/or reduces the likelihood of corruption of data encoded in the output signals of the RF switch, and/or reduces the likelihood that harmonic distortion renders the RF switch inoperable, among other examples. Moreover, the shielding layer described herein enables the semiconductor device to be formed on low-cost silicon (Si) wafers instead of higher-cost trap-rich substrates such as silicon on insulator (SOI) wafers.

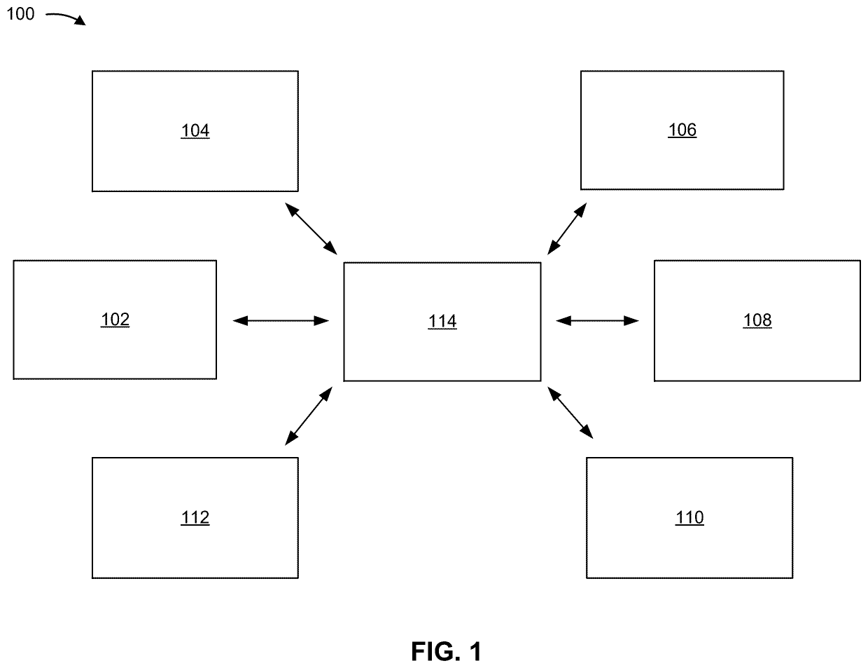

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

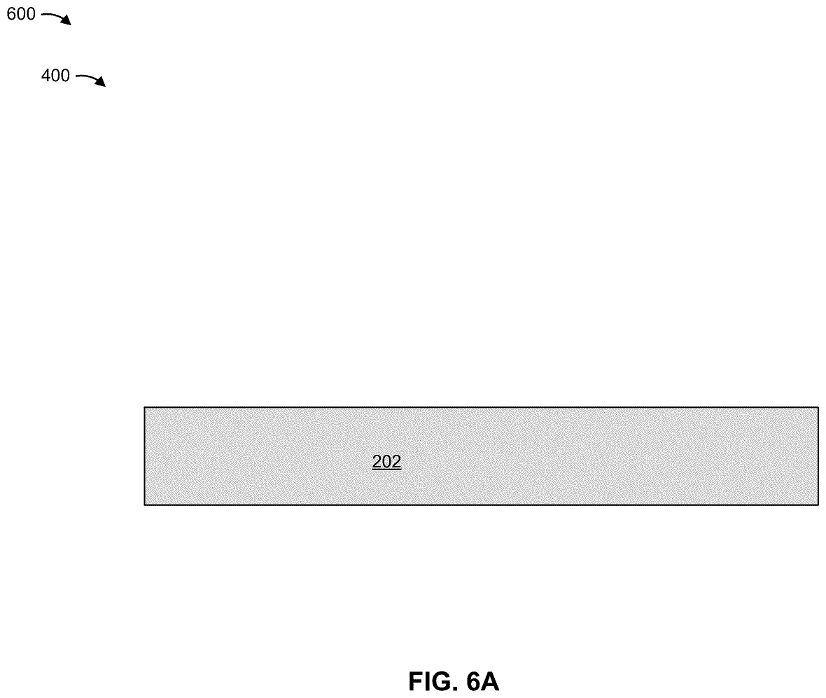

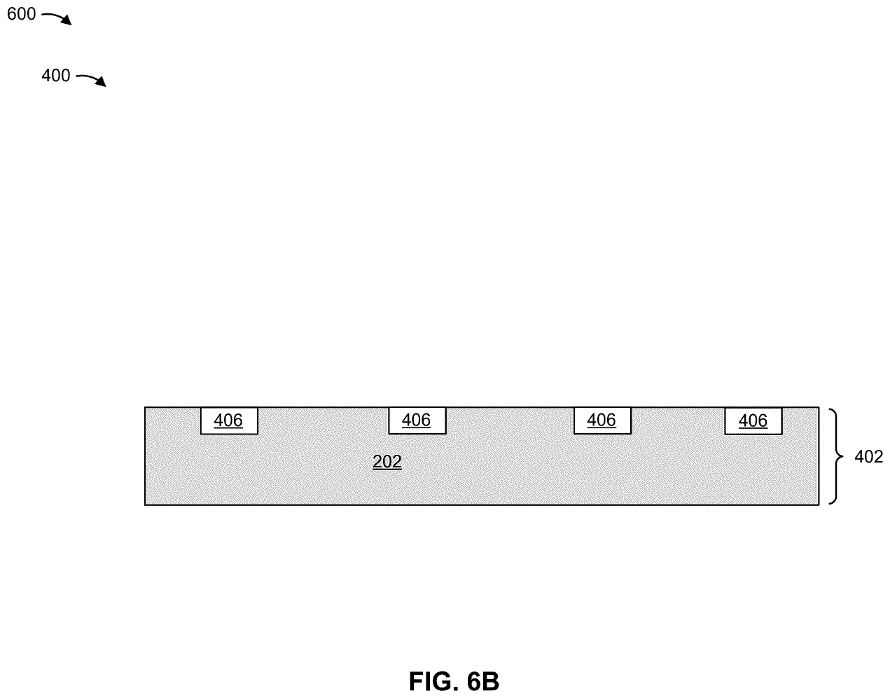

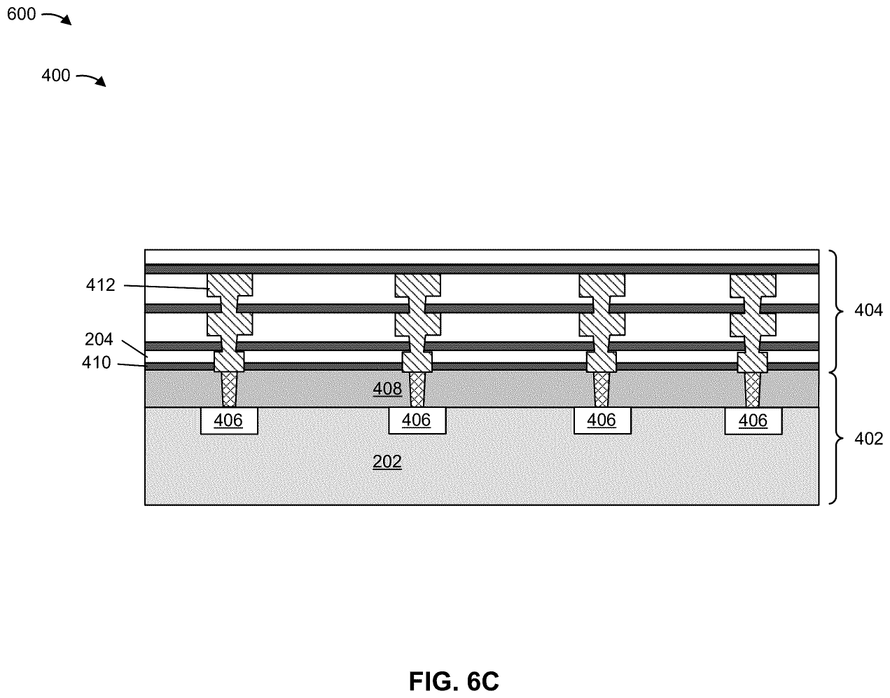

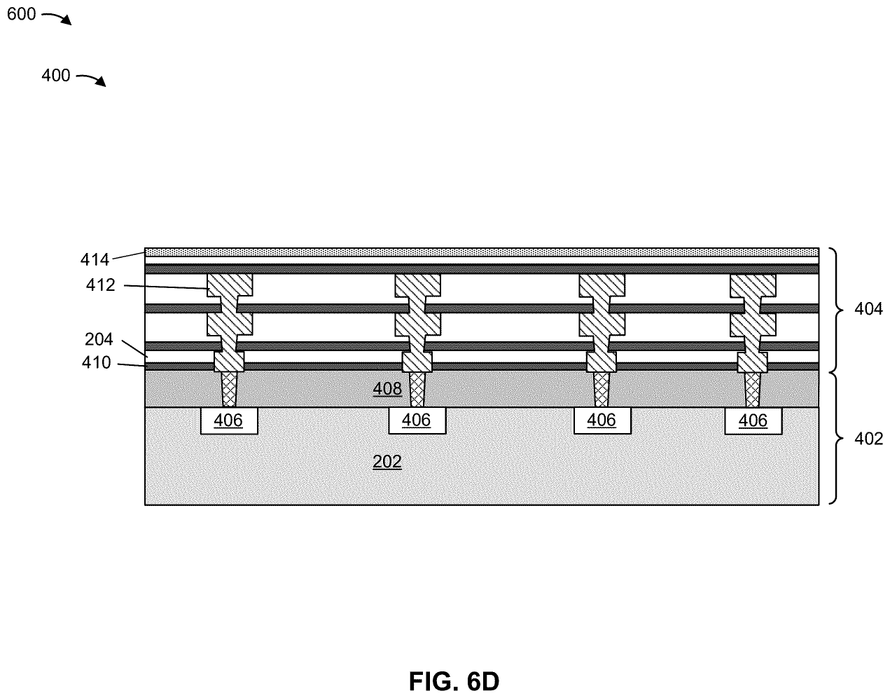

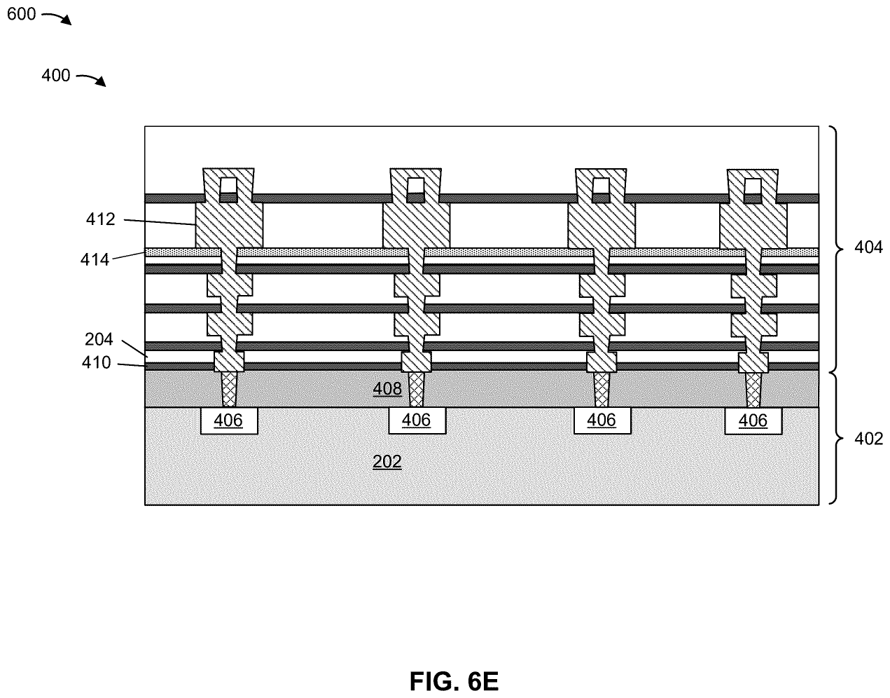

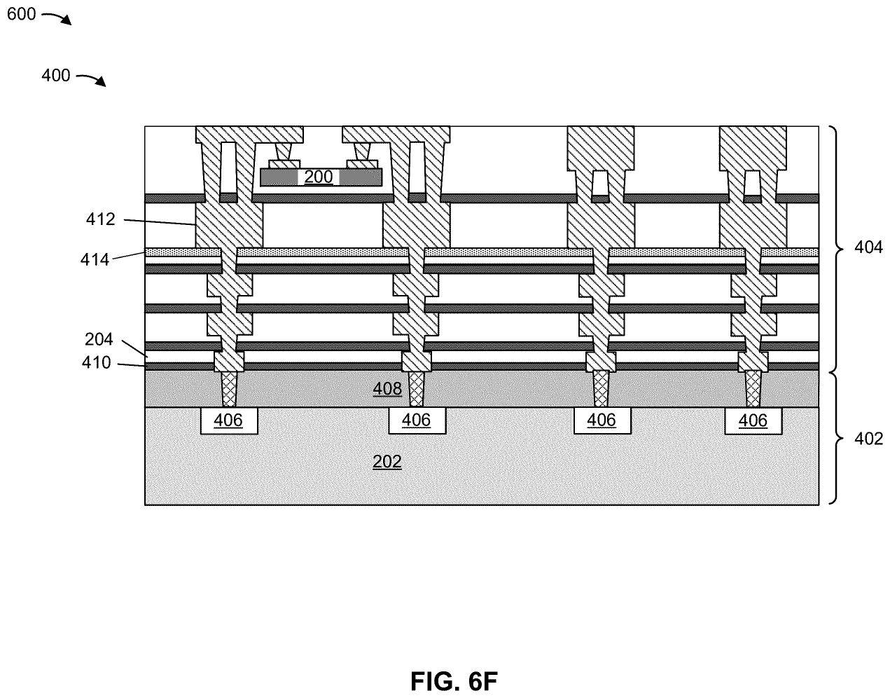

In some implementations, one or more of the semiconductor processing tools 102-112 and/or the wafer/die transport tool 114 may be used to perform one or more semiconductor processing operations described herein. For example, one or more of the semiconductor processing tools 102-112 and/or the wafer/die transport tool 114 may be used to form a plurality of active devices in a semiconductor substrate of a semiconductor device; may be used to form a first portion of an interconnect region, of the semiconductor device, above the semiconductor substrate; may form a shielding layer on the first portion of the interconnect region; may be used to form a second portion of the interconnect region over the shielding layer; and/or may be used to form an RF switch in the second portion of the interconnect region, among other examples. In some implementations, one or more of the semiconductor processing tools 102-112 and/or the wafer/die transport tool 114 may be used to perform one or more semiconductor processing operations described in connection with FIGS. 6A-6F, 7A-7J, 8A-8C, and/or 10, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

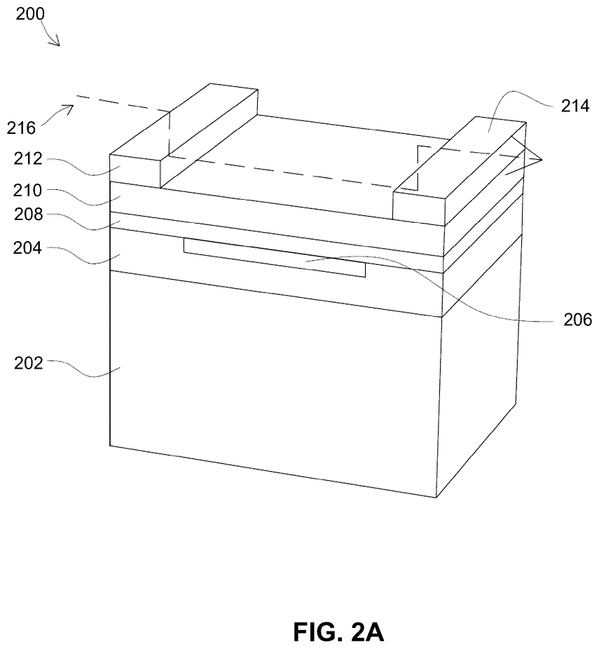

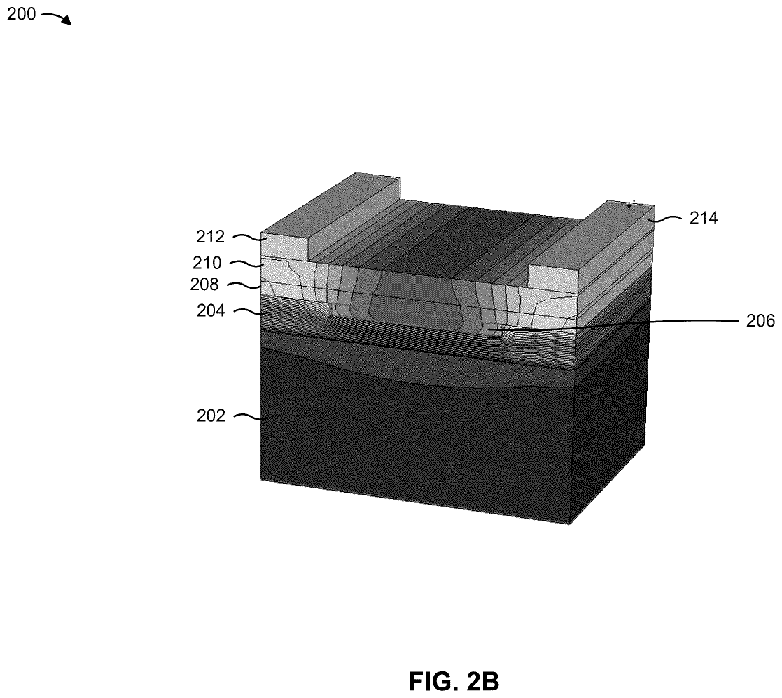

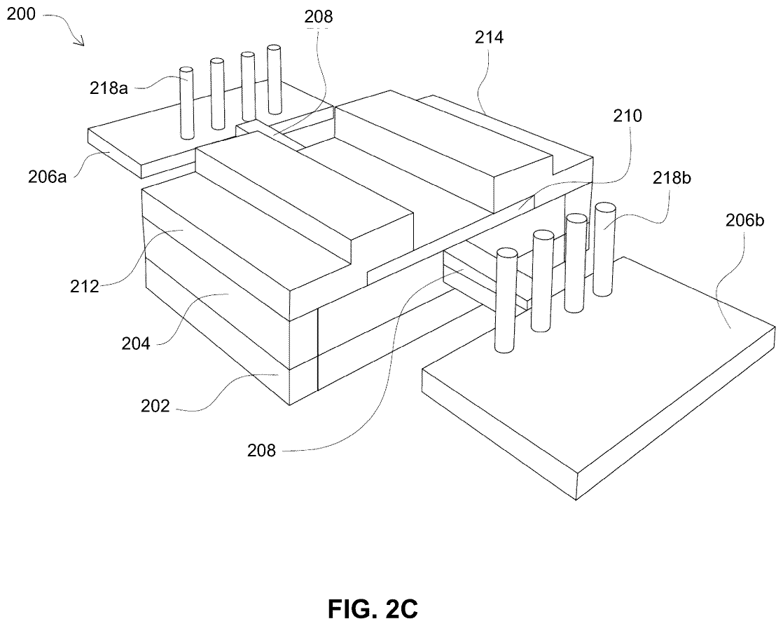

FIGS. 2A-2C are diagrams of an example RF switch 200 described herein. The RF switch 200 is an RF switch that operates at high frequencies by selectively transitions (or switches) between an “on” state and an “off” state. The RF switch 200 may include a phase change material (PCM) RF switch (PCM-RFS) that switches between the on state and the off state by selectively changing a phase of a switching material of the RF switch 200 between a crystalline phase and an amorphous phase.

As shown in FIG. 2A, the RF switch 200 may include a substrate 202. The RF switch 200 may include a dielectric layer 204 over and/or on the substrate 202. The RF switch 200 may include a heater 206 over, on, and/or recessed in the dielectric layer 204. The RF switch 200 may include an insulator layer 208 over and/or on the heater 206. The RF switch 200 may include a PCM layer 210 over and/or on the insulator layer 208. The RF switch 200 may include an RF in electrode 212 and an RF out electrode 214 over and/or on portions of the PCM layer 210.

The substrate 202 may include a silicon (Si) substrate. Alternatively, the substrate 202 may include a substrate formed of a material including silicon, a III-V compound semiconductor material substrate such as gallium arsenide (GaAs), a germanium substrate (Ge), a silicon germanium (SiGe) substrate, or another type of semiconductor substrate. In some implementations, the substrate 202 is doped with one or more types of dopants to form one or more dopant wells in the substrate 202.

The dielectric layer 204 may include a silicon oxide (SiOₓ such as SiO₂), a silicon oxynitride (SiON), and/or another oxide-containing material. Additionally and/or alternatively, the dielectric layer 204 may include another insulating material or another dielectric layer having a suitable thermal conductivity. The dielectric layer 204 may be formed to have a thermal conductivity that is included in a range of approximately 0.1 watts per meter kelvin (W/mk) to approximately 50 W/mk. However, other values for the range are within the scope of the present disclosure. The dielectric layer 204 may be formed to have a horizontal width that is included in a range of approximately 0.1 microns to approximately 2 microns. However, other values for the range are within the scope of the present disclosure. The dielectric layer 204 may be formed to have a horizontal length that is included in a range of approximately 2 microns to approximately 10 microns. However, other values for the range are within the scope of the present disclosure. The dielectric layer 204 may be formed to have a vertical thickness that is included in a range of approximately 0.16 microns to approximately 1.2 microns. However, other values for the range are within the scope of the present disclosure.

The heater 206 includes a region of material that is configured to conduct heat. The heater 206 may include a conductive material having a low Seebeck coefficient and a high melting point (e.g., approximately equal to or greater than 1500 degrees Celsius) such as tungsten (W) or molybdenum (Mo), among other examples. The high melting point enables the heater 206 to effectively heat the PCM layer 210 to switch the phase of the PCM layer 210 without melting the heater 206. The heater 206 may be formed to have a horizontal width that is included in a range of approximately 0.1 microns to approximately 2 microns. However, other values for the range are within the scope of the present disclosure. The heater 206 may be formed to have a horizontal length that is included in a range of approximately 0.1 microns to approximately 10 microns. However, other values for the range are within the scope of the present disclosure. The heater 206 may be formed to have a vertical thickness that is included in a range of approximately 0.05 microns to approximately 0.15 microns. However, other values for the range are within the scope of the present disclosure.

The insulator layer 208 may include an insulating material having a low dielectric constant (e.g., in a range of approximately 3 to approximately 10, among other examples) and/or a high thermal conductivity (e.g., approximately equal to or greater than 100 W/mk, among other examples). The low dielectric constant may enable the insulator layer 208 to resist the propagation of RF into the substrate 202. The high thermal conductivity may enable heat generated by the heater 206 to propagate into the PCM layer 210 through the insulator layer 208. In some implementations, the insulator layer 208 includes silicon nitride (SiₓN_{y} such as Si₃N₄). However, other materials may be used for the insulator layer 208.

The insulator layer 208 may be formed to have a horizontal width that is included in a range of approximately 5 microns to approximately 20 microns. However, other values for the range are within the scope of the present disclosure. The insulator layer 208 may be formed to have a horizontal length that is included in a range of approximately 5 microns to approximately 10 microns. However, other values for the range are within the scope of the present disclosure. The insulator layer 208 may be formed to have a vertical thickness that is included in a range of approximately 0.01 microns to approximately 0.05 microns. However, other values for the range are within the scope of the present disclosure.

The PCM layer 210 may correspond to the switching material of the RF switch 200. The phase of the PCM layer 210 may be switched to selectively permit the propagation of an RF signal 216 from the RF in electrode 212 to the RF out electrode 214 through the PCM layer 210. Thus, the PCM layer 210 functions as the channel of the RF switch 200.

The PCM layer 210 includes one or more materials that are capable of transitioning between two or more material phases or crystal structure phases. In particular, the PCM layer 210 includes one or more materials that are capable of transitioning between a crystalline phase (or crystalline material structure) and an amorphous phase (or non-crystalline material structure). Examples of materials include chalcogenides (alloys containing group VI elements) such as binary chalcogenides, ternary chalcogenides, and/or quaternary chalcogenides, among other examples.

Examples of binary chalcogenides include germanium telluride (GeTe), germanium antimonide (GeSb), gallium antimonide (GaSb), indium antimonide (InSb), antimony telluride (SbₓTe_{y} such as Sb₂Te₃), and/or indium selenide (InSe), among other examples.

Examples of ternary chalcogenides include germanium antimony tellurium (GeₓSb_{y}Te_{z} such as Ge₂Sb₂Te₅), indium antimony tellurium (InSbTe), gallium selenide telluride (GaSeTe), tin antimony telluride (SnSbₓTe_{y} such as SnSb₂Te₄), indium antimony germanium (InSbGe), and/or gallium antimony telluride (GaSbTe), among other examples. For germanium antimony tellurium, the respective concentration of germanium, antimony, and tellurium may be selected to achieve a particular phase transition speed and/or a particular high temperature data retention (HTDR), among other examples.

Examples of quaternary chalcogenides include silver indium antimony tellurium (AgInSbTe), germanium-doped antimony telluride ((Ge)SbTe), tin-doped antimony telluride ((Sn)SbTe), selenide-doped germanium antimonide (GeSb(Se)), tellurium-doped germanium antimonide (GeSb(Te)), tellurium germanium antimony sulfur (Te_{w}GeₓSb_{y}S_{z} such as Te₈₁Ge₁₅Sb₂S₂), germanium antimony tellurium with oxygen (GeₓSb_{y}Te_{z}:O such as Ge₂Sb₂Te₅:O), and/or germanium antimony tellurium with nitrogen (GeₓSb_{y}Te_{z}:N such as Ge₂Sb₂Te₅:N), among other examples.

The PCM layer 210 may be formed to have a horizontal width that is included in a range of approximately 0.1 microns to approximately 10 microns. However, other values for the range are within the scope of the present disclosure. The PCM layer 210 may be formed to have a horizontal length that is included in a range of approximately 0.1 microns to approximately 10 microns. However, other values for the range are within the scope of the present disclosure. The PCM layer 210 may be formed to have a vertical thickness that is included in a range of approximately 0.05 microns to approximately 0.1 microns. However, other values for the range are within the scope of the present disclosure.

The RF in electrode 212 and the RF out electrode 214 may be spaced apart by a distance such that the RF signal 216 traverses through the PCM layer 210 between the RF in electrode 212 and the RF out electrode 214, as opposed to directly from the RF in electrode 212 to the RF out electrode 214. The RF in electrode 212 and the RF out electrode 214 may each include one or more conductive materials to enable the RF in electrode 212 and the RF out electrode 214 to conduct the RF signal 216 (which may include a time-varying electrical signal). Examples of conductive materials include gold (Au), titanium, and/or another conductive material.

Each of the RF in electrode 212 and the RF out electrode 214 may be formed to have a horizontal width that is included in a range of approximately 5 microns to approximately 10 microns. However, other values for the range are within the scope of the present disclosure. Each of the RF in electrode 212 and the RF out electrode 214 may be formed to have a horizontal length that is included in a range of approximately 5 microns to approximately 10 microns. However, other values for the range are within the scope of the present disclosure. Each of the RF in electrode 212 and the RF out electrode 214 may be formed to have a vertical thickness that is included in a range of approximately 0.05 microns to approximately 0.1 microns. However, other values for the range are within the scope of the present disclosure.

FIG. 2B illustrates an example temperature gradient in the RF switch 200 during operation of the RF switch 200. As shown in FIG. 2B, the temperature may be highest in the heater 206 as the heater 206 generates heat. The heat propagates through the insulator layer 208 and into the PCM layer 210. A high current (Iₕₑₐₜₑᵣ) may be provided to the heater 206 to create joule heating in heater 206 to generate a high local temperature (e.g., approximately 1000 degrees kelvin or greater, among other examples). Different Iₕₑₐₜₑᵣ profiles, and thus, different local temperature temporal profiles, may be used to transition the PCM layer 210 from a crystalline phase to an amorphous phase, and from an amorphous phase to a crystalline phase.

As shown in FIG. 2C, the RF switch 200 may include additional structures and/or layers. For example, the RF switch 200 may include a plurality of heater regions 206a and 206b to achieve an even distribution of heat under the PCM layer 210. Vias 218a and 218b may be respectively connected to the heater regions 206a and 206b to connect the heater regions 206a and 206b with heat sinks to provide rapid cooling of the heater regions 206a and 206b.

As indicated above, FIGS. 2A-2C are provided as examples. Other examples may differ from what is described with regard to FIGS. 2A-2C.

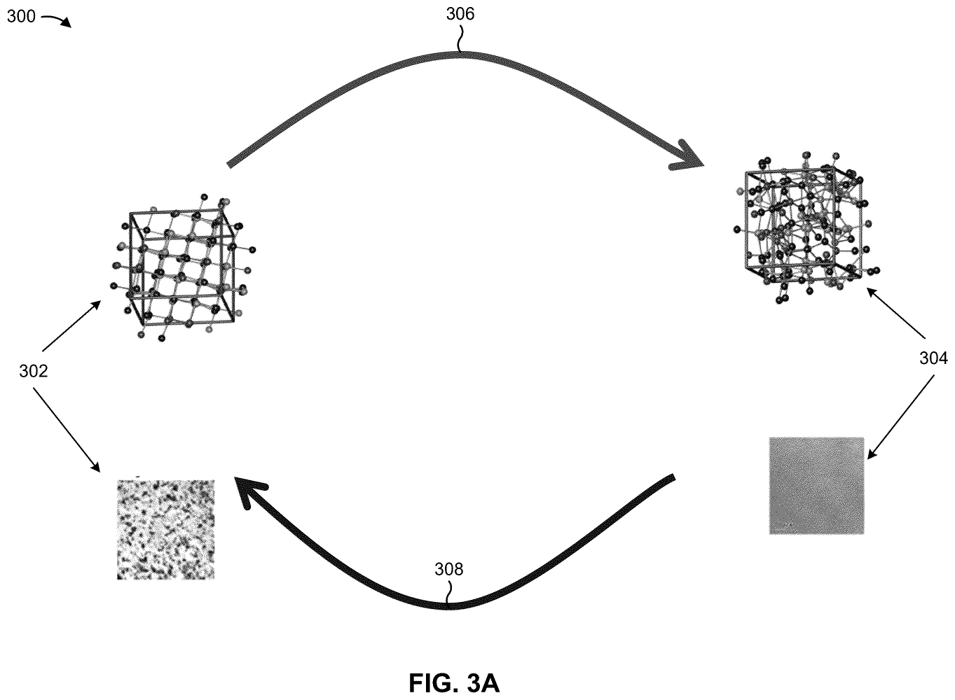

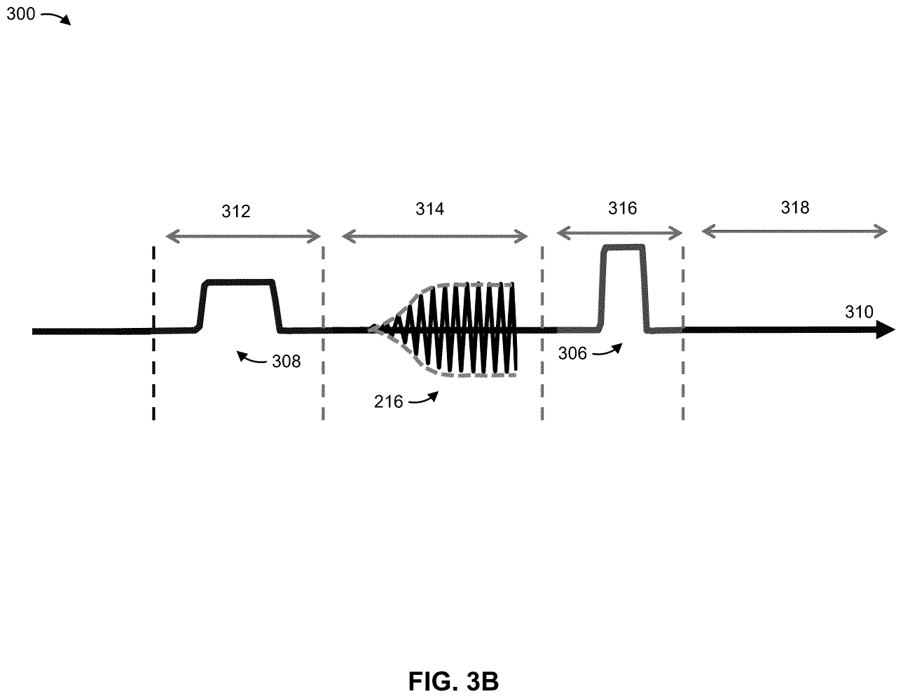

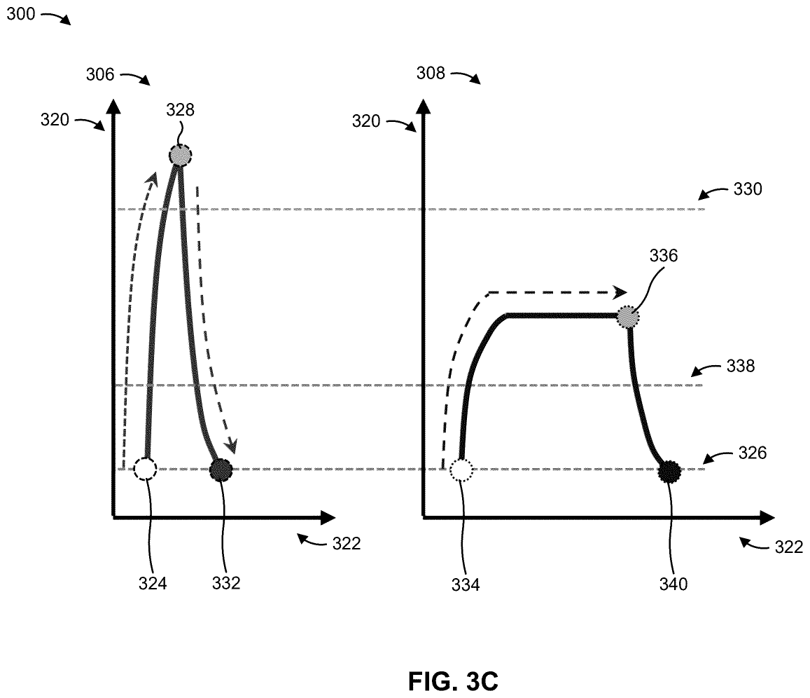

FIGS. 3A-3C are diagrams of example implementations 300 of the operation of the RF switch 200 described herein.

As shown in FIG. 3A, the PCM layer 210 of the RF switch 200 may be transitioned between a crystalline phase 302 and an amorphous phase 304. In the crystalline phase 302, the material structure of the PCM layer 210 is arranged in an ordered and approximately crystalline structure. In the amorphous phase 304, the material structure of the PCM layer 210 is non-crystalline and/or disordered. The crystalline phase 302 may correspond to the on state of the RF switch 200. In the crystalline phase 302, the PCM layer 210 has relatively low resistivity (e.g., relative to the resistivity in the off state), which enables the RF signal 216 to propagate through the PCM layer 210. The amorphous phase 304 may correspond to the off state of the RF switch 200. In the amorphous phase 304, the PCM layer 210 has relatively high resistivity (e.g., relative to the resistivity in the on state), which prevents the RF signal 216 from propagating through the PCM layer 210.

As further shown in FIG. 3A, a reset operation 306 may be performed to transition the PCM layer 210 from the crystalline phase 302 to the amorphous phase 304. A set operation 308 may be performed to transition the PCM layer 210 from the amorphous phase 304 to the crystalline phase 302. The reset operation 306 and the set operation 308 may each include providing a current (Iₕₑₐₜₑᵣ) to the heater 206 to cause the heater 206 to heat (increase the temperature of) the PCM layer 210 to a particular temperature and for a particular time duration.

As shown in FIG. 3B, the set operation 308 may be performed for a transition period 312 along a timeline 310 to transition the RF switch 200 to the on state. In the on state, the RF signal 216 may propagate through the PCM layer 210 from the RF in electrode 212 to the RF out electrode 214. In an example use case, the RF signal 216 may propagate from a modem of a wireless communication device to an antenna of the wireless communication device through the RF switch 200 during a signal transmission period 314 so that the RF signal 216 may be wirelessly transmitted. Subsequently, the reset operation 306 may be performed for a transition period 316 to transition the RF switch 200 from the on state to the off state. In the off state, the PCM layer 210 block the propagation of RF signals between the RF in electrode 212 to the RF out electrode 214 for an off duration 318.

FIG. 3C illustrates example temperature profiles for the reset operation 306 and for the set operation 308. The temperature profiles are illustrated as a function of the temperature 320 of the PCM layer 210 and time 322.

In the temperature profile for the reset operation 306, the temperature 320 of the PCM layer 210 may be at a starting temperature 324, which may correspond to a baseline temperature 326 (e.g., room temperature or a baseline operating temperature of the RF switch 200 with the heater 206 off). The heater 206 is subsequently activated by providing a current to the heater 206, which causes the heater 206 to generate heat and increase in temperature. The heat generated by the heater 206 causes the temperature 320 of the PCM layer 210 to also increase from the starting temperature 324.

In the reset operation 306, the temperature 320 of the PCM layer 210 is quickly and rapidly increases to a reset temperature 328. The reset temperature 328 is greater than a melting temperature 330 of the PCM layer 210. Heating the PCM layer 210 such that the temperature 320 of the PCM layer 210 increases to greater than the melting temperature 330 of the PCM layer 210 causes the material of the PCM layer 210 to melt. An example of the melting temperature 330 may be approximately 1000 degrees kelvin. However, other values for the melting temperature 330 are within the scope of the present disclosure.

The heater 206 is subsequently deactivated, and the material of the PCM layer 210 is quenched such that the temperature 320 of the PCM layer 210 rapidly decreases back to an ending temperature 332 corresponding to the baseline temperature 326. The rapid heating (above the melting temperature 330) and cooling of the PCM layer 210 causes the material of the PCM layer 210 to transition from the crystalline phase 302 to the amorphous phase 304.

In the temperature profile for the set operation 308, the temperature 320 of the PCM layer 210 may be at a starting temperature 334, which may correspond to a baseline temperature 326 (e.g., room temperature or a baseline operating temperature of the RF switch 200 with the heater 206 off). The heater 206 is subsequently activated by providing a current to the heater 206, which causes the heater 206 to generate heat and increase in temperature. The heat generated by the heater 206 causes the temperature 320 of the PCM layer 210 to also increase from the starting temperature 334.

In the set operation 308, the temperature 320 of the PCM layer 210 is increased to and maintained at a set temperature 336. The PCM layer 210 is maintained at the set temperature 336 for a greater time duration than the reset temperature 328. For example, the time duration of the set operation 308 may be on the order of a few microseconds (e.g., 1-5 microsections), whereas the time duration of the reset operation 306 may be on the order of nanoseconds (e.g., 100-200 nanoseconds). The set temperature 336 is less than the reset temperature 328. In particular, the set temperature 336 is greater than a crystallization temperature 338 of the material of the PCM layer 210 and less than the melting temperature 330 of the material of the PCM layer 210. An example of the crystallization temperature 338 may be approximately 500 degrees kelvin. However, other values for the crystallization temperature 338 are within the scope of the present disclosure. A greater voltage magnitude may be applied to the heater 206 to heat the PCM layer 210 to a greater temperature in the reset operation 306 relative to the voltage magnitude that is applied to the heater 206 to heat the PCM layer 210 in the set operation 308.

Heating the PCM layer 210 such that the temperature 320 of the PCM layer 210 increases to greater than the crystallization temperature 338 and less than the melting temperature 330 causes the material of the PCM layer 210 to crystalize (or recrystallize), which causes the material of the PCM layer 210 to transition from the amorphous phase 304 to the crystalline phase 302. The heater 206 is subsequently deactivated, and the material of the PCM layer 210 is quenched such that the temperature 320 of the PCM layer 210 decreases to an ending temperature 340 that corresponds to the baseline temperature 326.

As indicated above, FIGS. 3A-3C are provided as examples. Other examples may differ from what is described with regard to FIGS. 3A-3C.

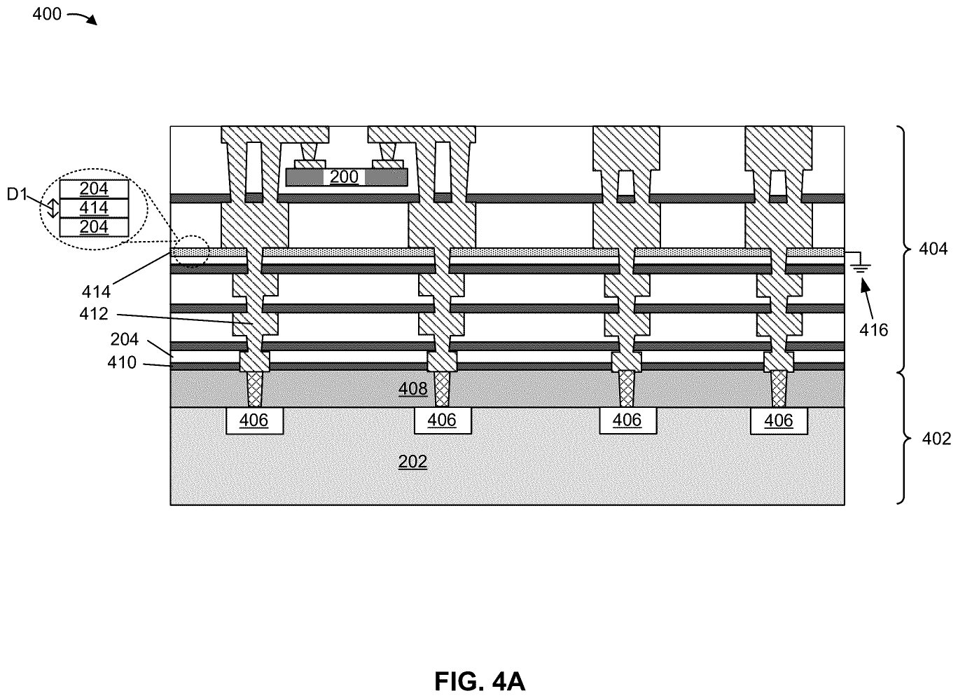

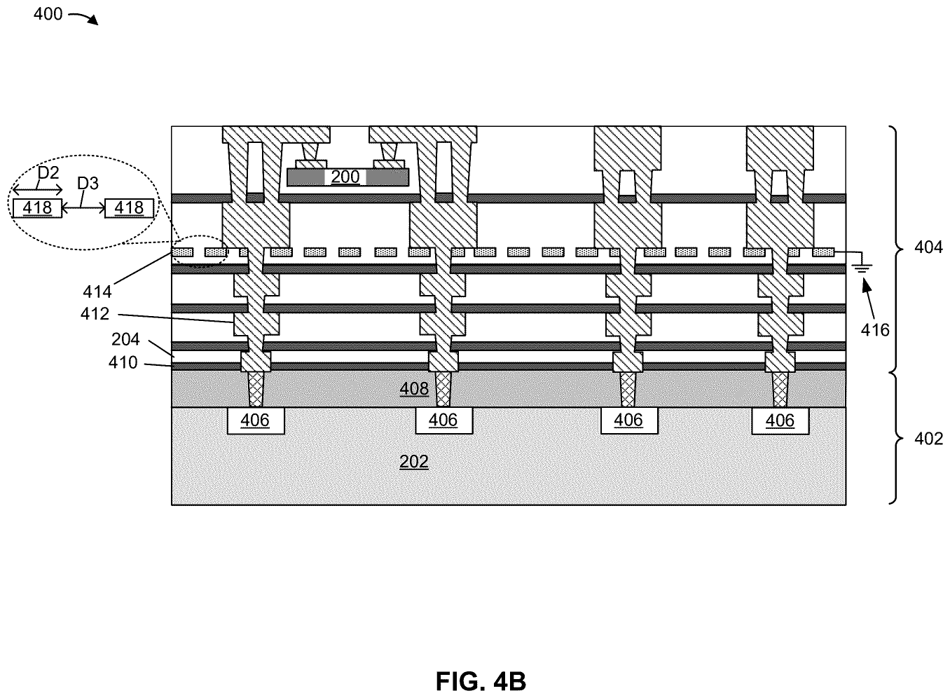

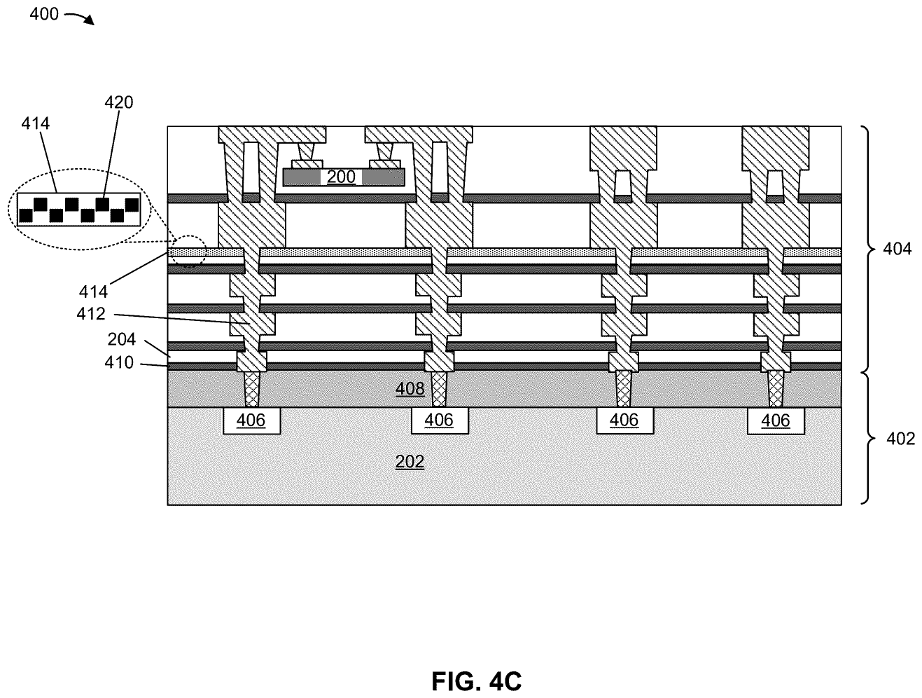

FIGS. 4A-4C are diagrams of example implementations of an example semiconductor device 400 described herein. In some implementations, the semiconductor device 400 includes a monolithic system on chip (SoC) die that includes a plurality of different functionalities, such as an RF front-end device, a baseband device, and/or another type of wireless communication device. In some implementations, the semiconductor device 400 includes a chiplet, which is a type of semiconductor die that includes a specific subset of functionalities of an overall semiconductor device package. For example, an RF front-end device may include a plurality of chiplets that are packaged on a semiconductor package substrate. A chiplet may correspond to a power amplifier die, a filter die, an RF switch die, an antenna switch die, and/or an antenna tuner die, among other examples. The chiplets may be electrically connected through redistribution layers in the semiconductor package substrate, and/or may be stacked in a system on integrated chips (SoIC) manner such that two or more chiplets are directly bonded and interconnected. Implementing chiplets on a semiconductor package substrate (e.g., as opposed to a monolithic die that includes the entire suite of functionalities) enables advancements to be realized for specific functionalities without having to necessarily redesign semiconductor dies for other functionalities.

As shown in an example implementation of the semiconductor device 400 in FIG. 4A, the semiconductor device 400 may include a device region 402 and an interconnect region 404. The device region 402 includes the substrate 202 and a plurality of active devices 406 that are included in and/or on the substrate 202. The active devices 406 include transistors (e.g., planar transistors, fin field effect transistors (finFETs), gate all around (GAA) transistors), pixel sensors, photodetectors, transceivers, transmitters, receives, optical circuits, and/or other types of semiconductor devices.

A dielectric layer 408 is included over the substrate 202. The dielectric layer 408 includes an interlayer dielectric (ILD) layer, an etch stop layer (ESL), and/or another type of dielectric layer. The dielectric layer 408 includes dielectric material(s) that enable various portions of the substrate 202 and/or the active devices 406 to be selectively etched or protected from etching, and/or to electrically isolate the active devices 406 in the device region 402. The dielectric layer 408 includes a silicon nitride (SiₓN_{y}), an oxide (e.g., a silicon oxide (SiOₓ) and/or another oxide material), and/or another type of dielectric material.

The interconnect region 404 is included above the substrate 202 and above the active devices 406. The interconnect region 404 includes dielectric layers, and the dielectric layers may include dielectric layers 204 and ESLs 410 that are arranged in an alternating manner. The dielectric layers 204 the ESLs 410 may be arranged in a direction that is approximately perpendicular to the substrate 202. The dielectric layers 204 may each include an oxide (e.g., a silicon oxide (SiOₓ) and/or another oxide material), an undoped silicate glass (USG), a boron-containing silicate glass (BSG), a fluorine-containing silicate glass (FSG), and/or another suitable dielectric material. In some implementations, a dielectric layer 204 includes an ELK dielectric material having a dielectric constant that is less than approximately 2.5. The ESLs 410 may each include a silicon nitride (SiₓN_{y}), silicon carbide (SiC), silicon oxynitride (SiON), and/or another suitable dielectric material. In some implementations, a dielectric layer 204 and an ESL 410 include different dielectric materials to provide etch selectivity to enable various structures to be formed in the interconnect region 404.

The interconnect region 404 includes a plurality of metallization layers 412. The metallization layers 412 are electrically coupled and/or physically coupled with one or more of the active devices 406 in the device region 402. The metallization layers 412 correspond to circuitry that enables signals and/or power to be provided to and/or from the active devices 406. The metallization layers 412 each include vias, trenches, contacts, plugs, interconnects, and/or other types of conductive structures. The metallization layers 412 each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

In some implementations, the metallization layers 412 of the interconnect region 404 may be arranged in in a vertical manner. In other words, a plurality of stacked metallization layers 412 extend between the device region 402 and a top of the interconnect region 404 to facilitate electrical signals and/or power to be routed between the device region 402 and the top of the interconnect region 404. The plurality of stacked metallization layers 412 may be referred to as M-layers. For example, a metal-0 (M0) layer may located at the bottom of the interconnect region 404 and may be directly coupled with the device region 402 (e.g., with the contacts or interconnects of the active devices 406 in the device region 402), a metal-1 layer (M1) layer may be located above the M0 layer in the interconnect region 404, a metal-2 layer (M2) layer may be located above the M1 layer, and so on. In some implementations, the interconnect region 404 includes nine (9) stacked metallization layers 412 (e.g., M0-M8). In some implementations, the interconnect region 404 includes another quantity of stacked metallization layers 412.

The interconnect region 404 includes an RF switch 200 in a dielectric layer 204. In some implementations, the interconnect region 404 includes other active devices 406, such as a memory device, a resistor, a capacitor, and/or an optical modulator, among other examples. The interconnect region 404 also includes a shielding layer 414 between the RF switch 200 and the substrate 202. Thus, the shielding layer 414 may be located below and/or under the RF switch 200. The shielding layer 414 is included to block, prevent, or reduce the propagation of E-field emissions and/or H-field emissions from the RF switch 200 from reaching the substrate 202, which might otherwise result in a parasitic current being induced in the substrate 202. The shielding layer 414 may be coupled with an electrical grounding path 416 of the semiconductor device 400 to facilitate E-field emissions blocking. The shielding layer 414 may be included in a dielectric layer 204, between a dielectric layer 204 and an ESL 410, among other examples.

The shielding layer 414 may include a continuous layer of a metal material such as aluminum (Al), copper (Cu), tungsten (W), cobalt (Co), nickel (Ni), tantalum (Ta), titanium (Ti), zirconium (Zr), a nickel-containing material, a cobalt-containing material, a tantalum-containing material, a titanium-containing material, a zirconium-containing material, and/or an iron-containing material, among other examples. Examples include tantalum nitride (TaN), titanium nitride (Ti), nickel iron (NiFe), cobalt iron (CoFe), nickel cobalt (NiCo), nickel cobalt iron (NiCoFe), and/or cobalt zirconium tantalum (CoZrTa), among other examples. Additionally and/or alternatively, the shielding layer 414 may include an electrically semiconductive material such as polysilicon.

In some implementations, the material of the shielding layer 414 has an electrical conductivity that is greater than approximately 1×10⁶ siemens per meter (S/m). In some implementations, the material of the shielding layer 414 has an electrical conductivity that is included in a range of approximately 1×10⁶ S/m to approximately 1×10⁸ S/m to enable the shielding layer 414 to sufficiently suppress E-field emissions from the RF switch 200. However, other values for the range are within the scope of the present disclosure. In some implementations, the material of the shielding layer 414 has a permeability (e.g., a magnetic relative permeability (Ur)) that is included in a range of approximately 1 to approximately 5000 to enable the shielding layer 414 to sufficiently suppress H-field emissions from the RF switch 200. However, other values for the range are within the scope of the present disclosure.

In some implementations, the shielding layer 414 may have a thickness (illustrated in FIG. 4A as dimension D1) that is included in a range of approximately 200 nanometers to approximately 20 microns. If the thickness of the shielding layer 414 is less than approximately 200 nanometers, the shielding layer 414 may not have sufficient shielding capability. If the thickness of the shielding layer is greater than approximately 20 microns, the substrate 202 may experience increased parasitic coupling. If the thickness of the shielding layer 414 is included in the range of approximately 200 nanometers to approximately 20 microns, the shielding layer 414 may provide sufficient shielding and may enable a sufficiently low parasitic coupling to be achieved in the semiconductor device 400. However, other values for the thickness of the shielding layer 414, and ranges other than approximately 200 nanometers to approximately 20 microns, are within the scope of the present disclosure.

FIG. 4B illustrates an example implementation of the semiconductor device 400 in which the shielding layer 414 includes a plurality of discontinuous shielding segments 418 that are spaced apart by gaps corresponding to the dielectric layer 204. The shielding segments 418 may be discontinuous segments of shielding material that are electrically coupled with the electrical grounding path 416. The shielding segments 418 may provide increased blockage of parasitic currents in the substrate 202 relative to the continuous layer of shielding material in the example implementation illustrated in FIG. 4A. However, the continuous layer of shielding material in the example implementation illustrated in FIG. 4A may be less complex (e.g., may take less time and fewer semiconductor processing resources) and less costly to manufacture than the shielding segments 418 illustrated in the example implementation of the semiconductor device 400 in FIG. 4B.

As shown in FIG. 4B, the shielding layer 414 may have one or more dimensions, such as a dimension D2 and a dimension D3, among other examples. The dimension D2 may correspond to a width of a shielding segment 418. In some implementations, the dimension D2 is included in a range of approximately 100 nanometers to approximately 10 microns. If the dimension D2 is less than approximately 100 nanometers, the shielding layer 414 may provide insufficient shielding of E-field emissions and/or H-field emissions in the semiconductor device 400. If the dimension D2 is greater than approximately 10 microns, the substrate 202 may experience increased parasitic coupling. If the dimension D2 is included in the range of approximately 100 nanometers to approximately 10 microns, the shielding layer 414 may provide sufficient shielding and may enable a sufficiently low parasitic coupling to be achieved in the semiconductor device 400. However, other values for the dimension D2, and ranges other than approximately 100 nanometers to approximately 10 microns, are within the scope of the present disclosure.

The dimension D3 may correspond to a spacing or a distance between shielding segments 418 in the shielding layer 414. In some implementations, the dimension D3 is included in a range of approximately 50 nanometers to approximately 1 micron. If the dimension D3 is less than approximately 50 nanometers, the substrate 202 may experience increased parasitic coupling. If the dimension D3 is greater than approximately 1 micron, the shielding layer 414 may provide insufficient shielding of E-field emissions and/or H-field emissions in the semiconductor device 400. If the dimension D3 is included in the range of approximately 50 nanometers to approximately 1 micron, the shielding layer 414 may provide sufficient shielding and may enable a sufficiently low parasitic coupling to be achieved in the semiconductor device 400. However, other values for the dimension D3, and ranges other than approximately 50 nanometers to approximately 1 micron, are within the scope of the present disclosure.

FIG. 4C illustrates an example implementation of the semiconductor device 400 in which the shielding layer 414 includes a plurality of shielding particles 420 that are suspended in a base material of the shielding layer 414. For example, the shielding particles 420 may include magnetic metal particles in an epoxy. Thus, the shielding layer 414 may include a metal-containing (e.g., iron-containing) epoxy material. The shielding particles 420 may provide increased performance for blocking H-field emissions from the RF switch 200. The shielding particles 420 may be electrically floating, meaning the shielding layer 414 in the example implementation of the semiconductor device 400 in FIG. 4C may not be electrically coupled with an electrical ground. The shielding particles 420 may be less than approximately 5 microns in diameter, and may have a diameter or width that is included in a range of approximately 100 nanometers to approximately 5 microns. However, other values for the range are within the scope of the present disclosure. Moreover, the shielding particles 420 may be arranged in the base material in an offset or staggered pattern, as shown in FIG. 4C. The offset pattern may enable the shielding particles 420 to block E-field emissions from the RF switch 200.

In some implementations, the semiconductor device 400 includes two or more of the example implementations of shielding layers 414 illustrated and described in connection with FIGS. 4A-4C. For example, the semiconductor device 400 may include a first shielding layer 414 having electrically floating shielding particles 420 for blocking H-field emissions from the RF switch 200, and a second shielding layer 414 having an electrically grounded continuous layer of material or electrically grounded shielding segments 418 for blocking E-field emissions from the RF switch 200.

As indicated above, FIGS. 4A-4C are provided as examples. Other examples may differ from what is described with regard to FIGS. 4A-4C.

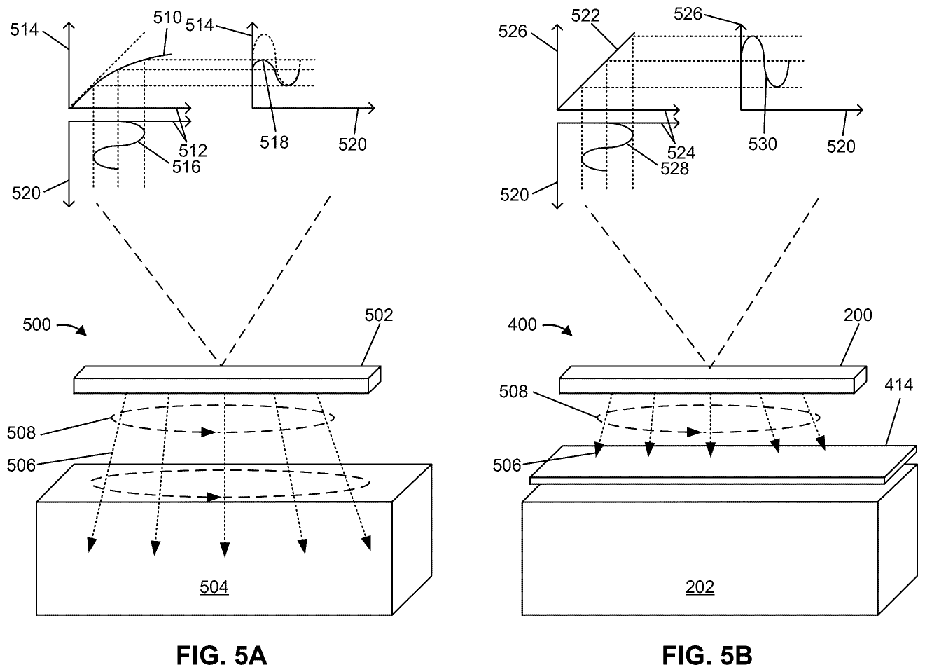

FIGS. 5A and 5B are diagrams of examples of H-field emissions and E-field emissions without and with the shielding layer 414 described herein. FIG. 5A illustrates an example of a semiconductor device 500 that does not include a shielding layer 414 described herein between an RF switch 502 and a substrate 504 of the semiconductor device 500. FIG. 5B illustrates an example of the semiconductor device 400 that includes the shielding layer 414 between the RF switch 200 and the substrate 202 of the semiconductor device 400.

As shown in FIG. 5A, the RF switch 502 emits H-field emissions 506 and E-field emissions 508 toward the substrate 504. The H-field emissions 506 include a time-varying magnetic field that induces the E-field emissions 508. The E-field emissions 508 are circular eddy currents about the H-field emissions 506 and cause electric current loops (parasitic current) to be induced in the substrate 504. The parasitic current causes a secondary H-field to be emitted back to the RF switch 502 from the substrate 504. The secondary H-field causes an impedance change in the RF switch 502, which results in a gain 510 of the RF switch 502 becoming nonlinear between an input voltage (vᵢ) 512 and an output voltage (vₒ) 514. This can cause distortion (e.g., harmonic distortion) between an input signal 516 to the RF switch 502 and an output signal 518. The input signal 516 is a time-varying signal that is a function of input voltage (vᵢ) 512 and time 520. The waveform of the input signal 516 may be a sine wave, a cosine wave, and/or another type of waveform. The gain 510 of the RF switch 502 being nonlinear results in distortion in the waveform of the output signal 518 generated by the RF switch 502.

As shown in FIG. 5B, the H-field emissions 506 and the E-field emissions 508 emitted by the RF switch 200 are blocked from propagating into the substrate 202, which prevents or reduces the likelihood of the H-field emissions 506 and the E-field emissions 508 causing a parasitic current to be induced in the substrate 202. The prevention of the parasitic current in the substrate 202 enables a gain 522 of the RF switch 200 to remain linear between an input voltage (vᵢ) 524 and an output voltage (vₒ) 526 of the RF switch 200. This enables the RF switch 200 to translate an input signal 528 to the RF switch 200 to an output signal 530 such that the output signal 530 is a linear output based on the input signal 528. The input signal 528 is a time-varying signal that is a function of input voltage (vᵢ) 524 and time 520. The waveform of the input signal 528 may be a sine wave, a cosine wave, and/or another type of waveform. The gain 522 of the RF switch 502 being linear results in minimal to no distortion in the waveform of the output signal 530 generated by the RF switch 502.

As indicated above, FIGS. 5A and 5B are provided as examples. Other examples may differ from what is described with regard to FIGS. 5A and 5B.

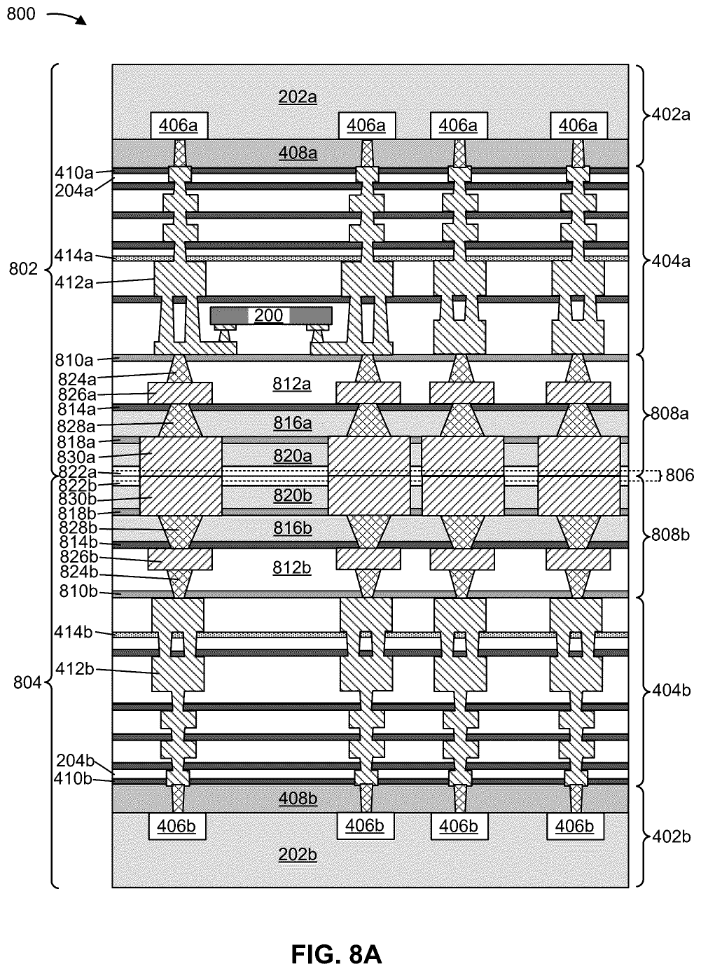

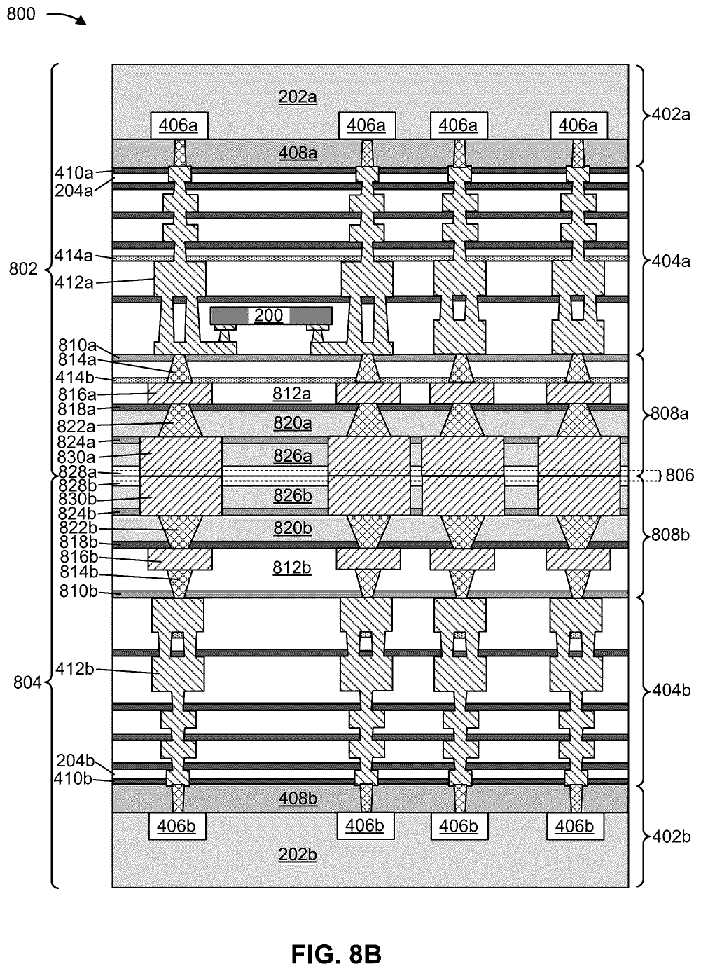

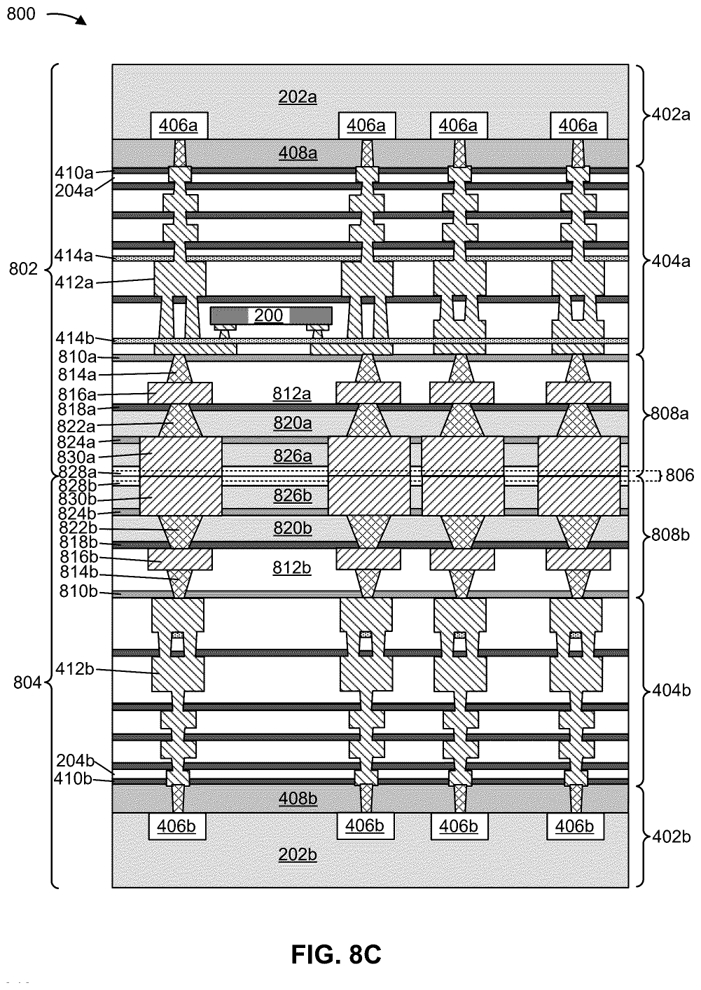

FIGS. 6A-6F are diagrams of an example implementation 600 of forming a semiconductor device 400 described herein. In some implementations, one or more of the semiconductor processing tools 102-112 and/or the wafer/die transport tool 114 may be used to perform one or more of the semiconductor processing operations described in connection with FIGS. 6A-6F. In some implementations, one or more of the semiconductor processing operations described in connection with FIGS. 6A-6F may be performed using another semiconductor processing tool. While the semiconductor processing operations are illustrated as being performed in connection with the semiconductor device 400, the semiconductor processing operations illustrated and described in connection with FIGS. 6A-6F may be performed to form a first semiconductor die 802 and/or a second semiconductor die 804 of the semiconductor device 800, of FIGS. 8A-8C, in a similar manner.

Turning to FIG. 6A, the substrate 202 is provided. The substrate 202 may be provided in the form of a semiconductor wafer such as a silicon (Si) wafer.

As shown in FIG. 6B, the active devices 406 may be formed in and/or on the substrate 202 in the device region 402 of the semiconductor device 400. One or more of the semiconductor processing tools 102-114 may be used to form one or more portions of the active devices 406. For example, a deposition tool 102 may be used to perform various deposition operations to deposit layers of the active devices 406, and/or to deposit photoresist layers for etching the substrate 202 and/or portions of the deposited layers. As another example, an exposure tool 104 may be used to expose the photoresist layers to form patterns in the photoresist layers. As another example, a developer tool 106 may develop the patterns in the photoresist layers. As another example, an etch tool 108 may be used to etch the substrate 202 and/or portions of the deposited layers to form the active devices 406. As another example, a planarization tool 110 may be used to planarize portions of the active devices 406. As another example, a plating tool 112 may be used to deposit metal structures and/or layers of the active devices 406.

As shown in FIG. 6C, a deposition tool 102 is used to deposit the dielectric layer 408 over and/or on the substrate 202 and over and/or on the active devices 406. A first portion of the interconnect region 404 of the semiconductor device 400 is then formed over the dielectric layer 408. A deposition tool 102 is used to deposit alternating layers of ESLs 410 and dielectric layers 204 of the first portion of the interconnect region 404 of the semiconductor device 400. A deposition tool 102, an exposure tool 104, a developer tool 106, an etch tool 108, a planarization tool 110, and/or a plating tool 112 are used to perform various operations to form the metallization layers 412 in the first portion of the interconnect region 404 of the semiconductor device 400. The metallization layers 412 may be included in the dielectric layers 204 and/or the ESLs 410, and may be electrically coupled with the active devices 406 in the device region 402.

As shown in FIG. 6D, the shielding layer 414 may be formed in the interconnect region 404 of the semiconductor device 400. The shielding layer 414 may be formed over and/or on the first portion of the interconnect region 404. In some implementations, the shielding layer 414 is formed on an ESL 410. In some implementations, the shielding layer 414 is formed on a dielectric layer 204. A deposition tool 102 may be used to deposit the shielding layer using a PVD technique, an ALD technique, a CVD technique, an oxidation technique, another type of deposition technique described in connection with FIG. 1, and/or another suitable deposition technique. In some implementations, a planarization tool 110 is used to planarize the shielding layer 414 after the shielding layer 414 is deposited.

In some implementations, the shielding layer 414 is etched to remove portions of the shielding layer 414 to form a segmented shielding layer 414 that includes a plurality of discontinuous shielding segments 418. In some implementations, a pattern in a photoresist layer is used to etch the shielding layer 414 to form the shielding segments 418 of the shielding layer 414. In these implementations, a deposition tool 102 may be used to form the photoresist layer on the shielding layer 414. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the shielding layer 414 based on the pattern to form the shielding segments 418 of the shielding layer 414. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the shielding layer 414 based on a pattern.

In some implementations, the shielding layer 414 is formed as a layer of shielding particles 420. In these implementations, the shielding layer 414 may be formed by forming a mixture that includes an epoxy precursor (or another type of base material precursor), the shielding particles 420, and a solvent such as propylene glycol methyl ether or dipropylene glycol dimethyl ether. The shielding particles 420 may be provided in the mixture as a metal powder, such an iron (Fe) powder among other examples, that is suspended in the epoxy precursor. A deposition tool 102 may be used to deposit a layer of the mixture onto the first portion of the interconnect region 404. The deposition tool 102 may be used to perform a baking operation on the layer of the mixture to form the shielding layer 414. The baking operation causes the solvent in the mixture to evaporate, thereby enabling the mixture to cure. The temperature of the layer of the mixture may be heated to an elevated temperature that is included in a range of approximately 120 degrees Celsius to approximately 140 degrees Celsius during baking operation. However, other values for the range are within the scope of the present disclosure. The temperature of the layer of the mixture may be maintained at the elevated temperature for a time duration that is included in a range of approximately 120 minutes to approximately 180 minutes. However, other values for the range are within the scope of the present disclosure.

As shown in FIG. 6E, a second portion of the interconnect region 404 of the semiconductor device 400 is then formed over and/or on the shielding layer 414. A deposition tool 102 is used to deposit alternating layers of ESLs 410 and dielectric layers 204 of the second portion of the interconnect region 404 of the semiconductor device 400. A deposition tool 102, an exposure tool 104, a developer tool 106, an etch tool 108, a planarization tool 110, and/or a plating tool 112 are used to perform various operations to form the metallization layers 412 in the second portion of the interconnect region 404 of the semiconductor device 400. The metallization layers 412 may be included in the dielectric layers 204 and/or the ESLs 410.

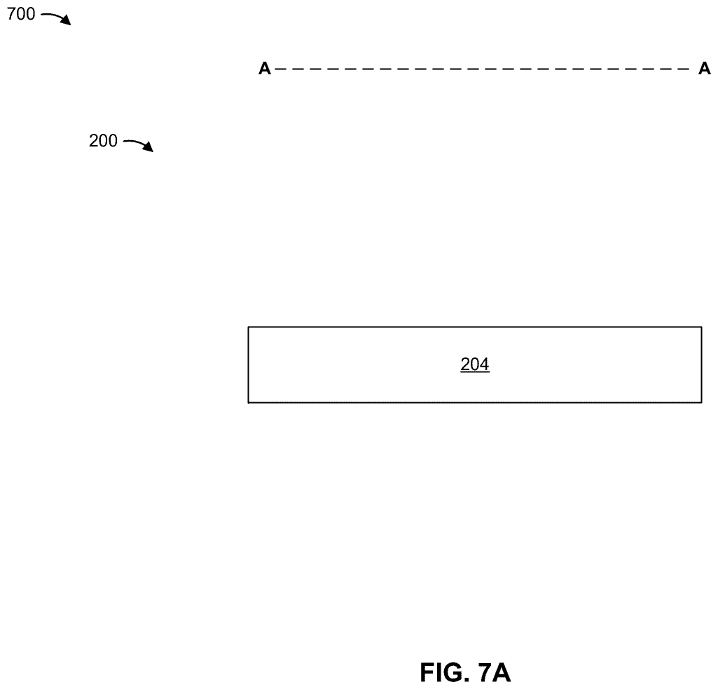

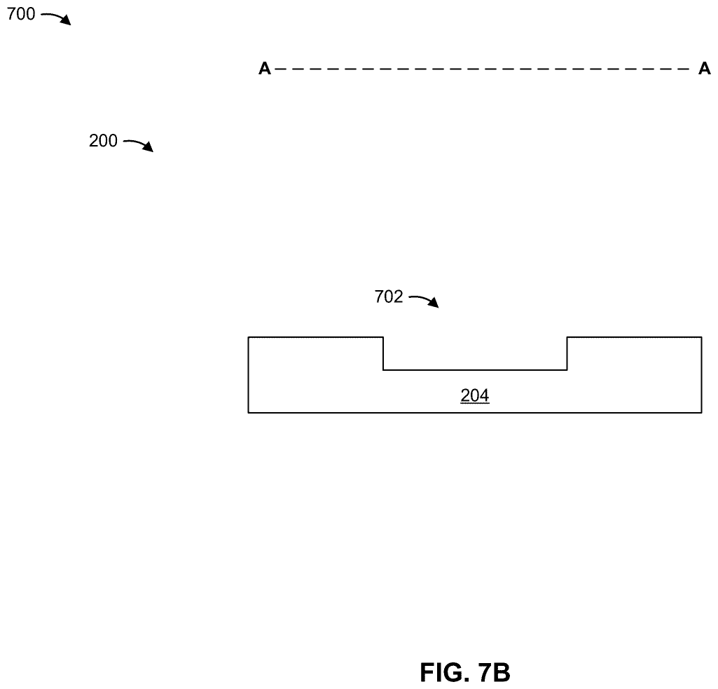

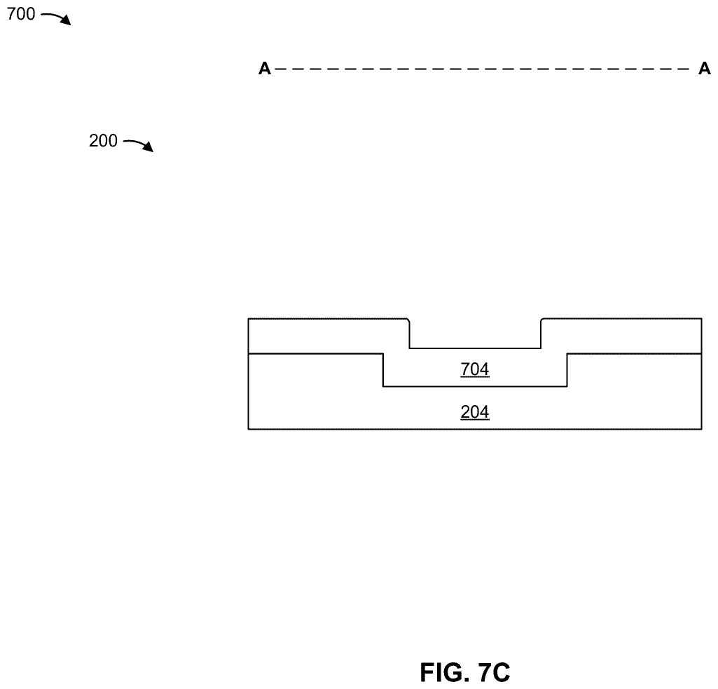

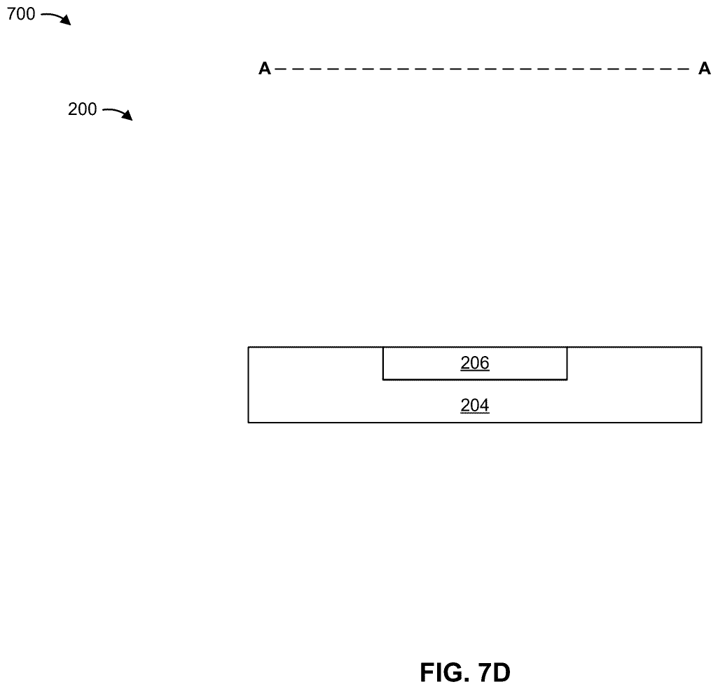

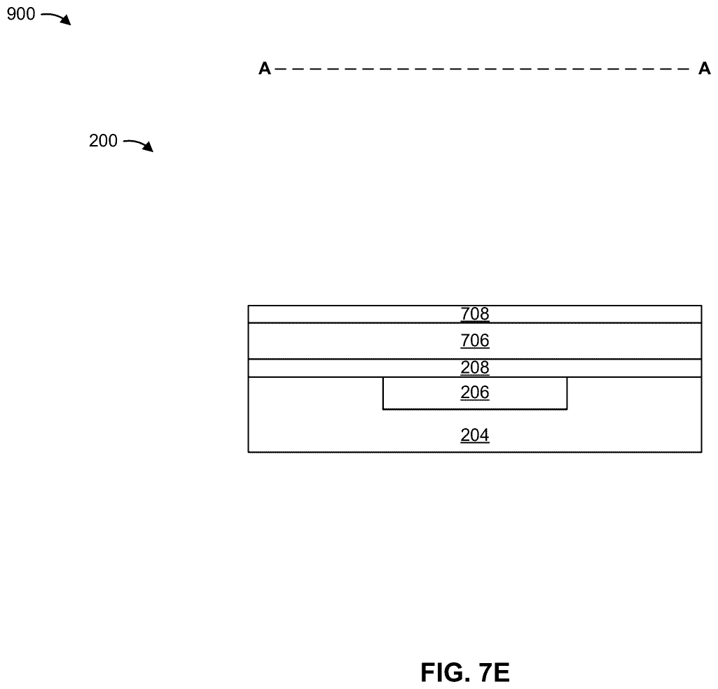

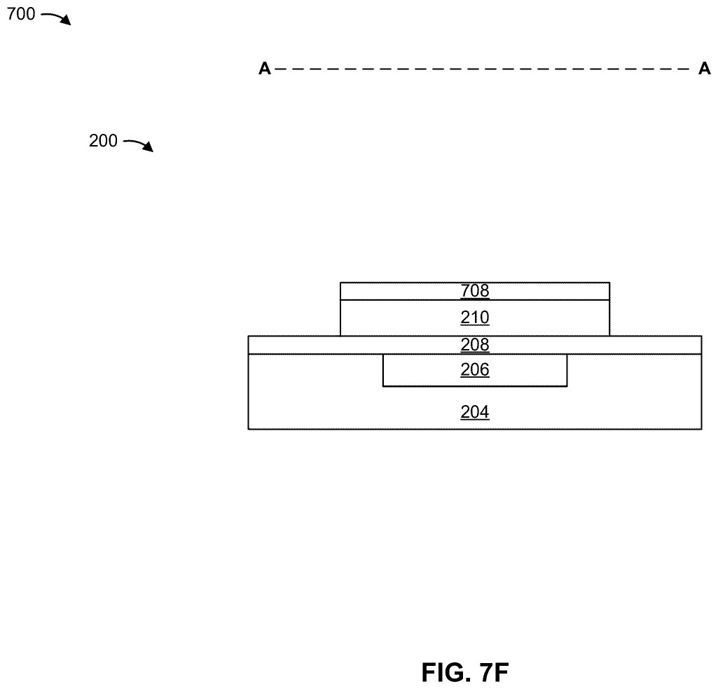

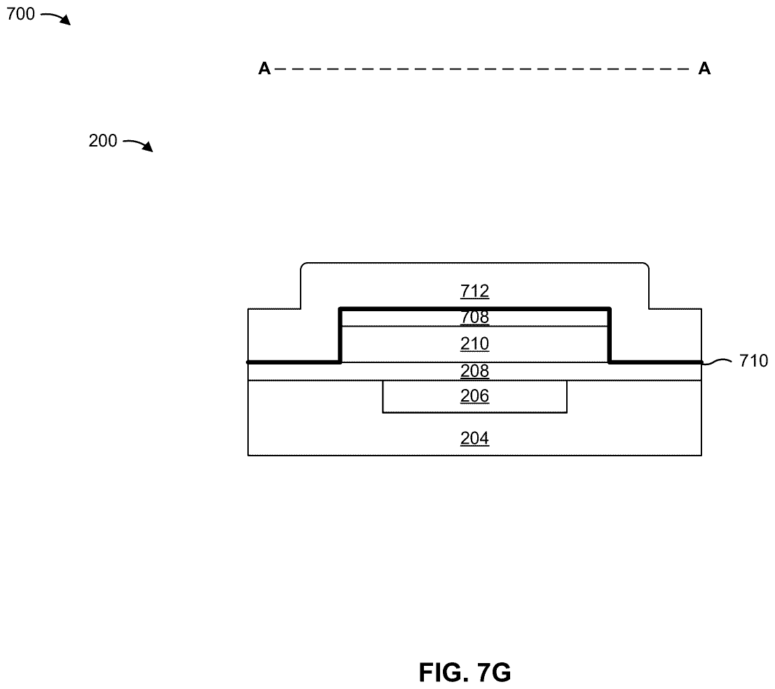

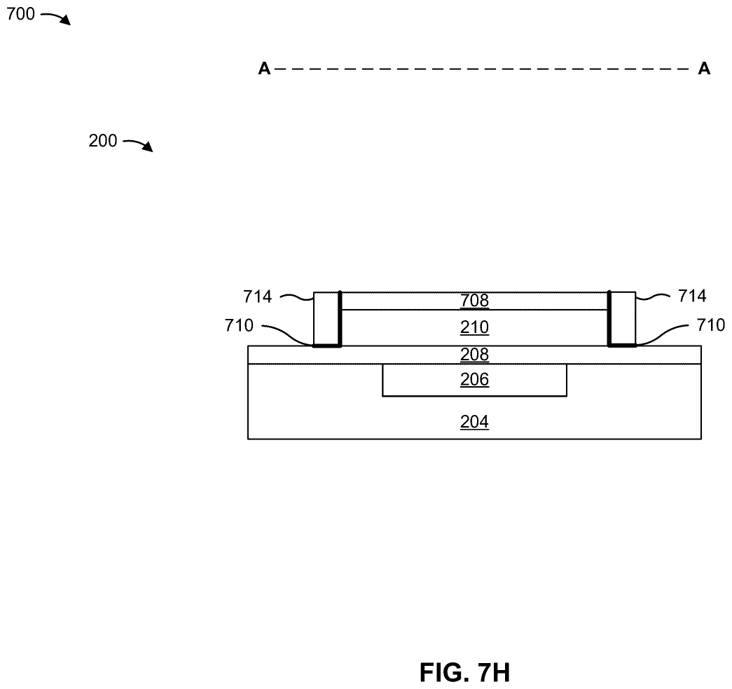

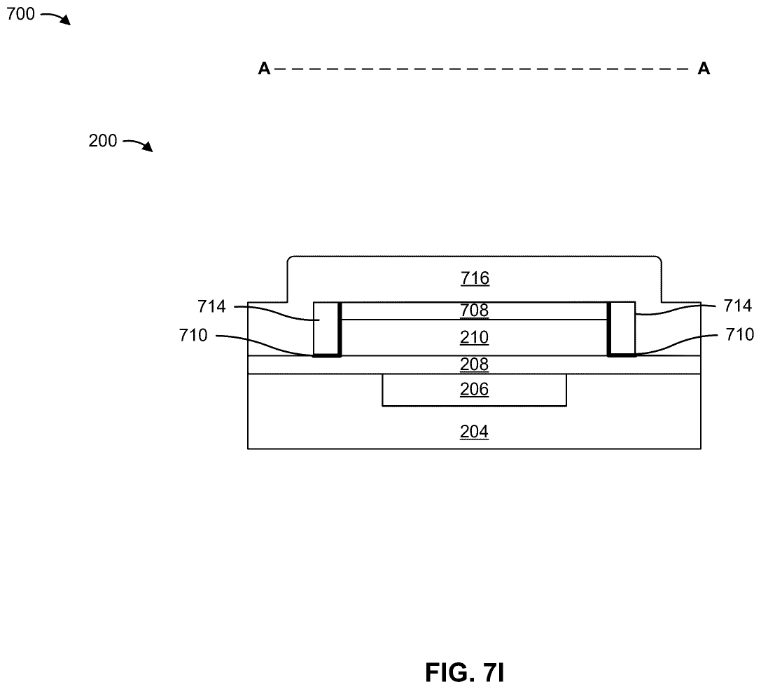

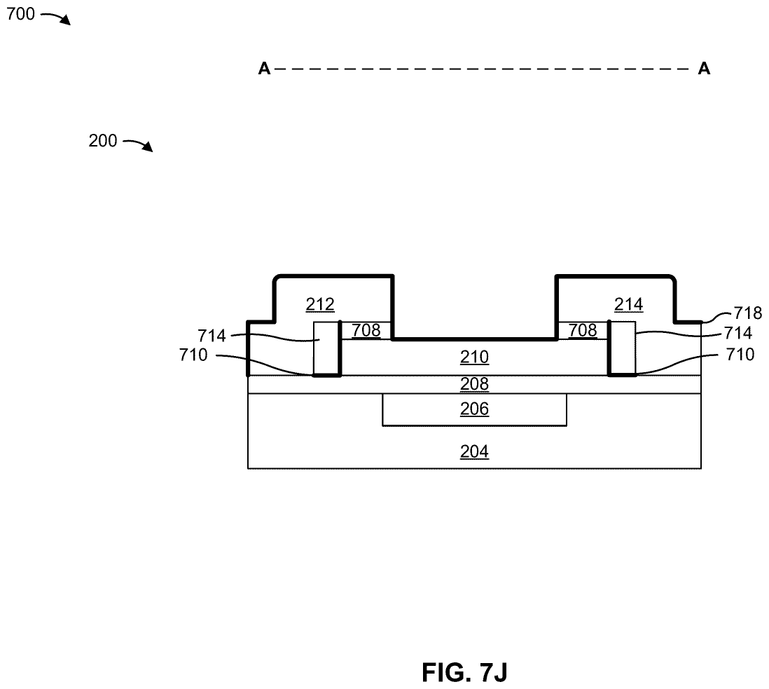

As shown in FIG. 6F, the RF switch 200 may be formed in the interconnect region 404 and electrically coupled and/or physically coupled to one or more metallization layers 412 in the interconnect region 404. The RF switch 200 may be formed in a dielectric layer 204 of the interconnect region 404. The RF switch 200 is formed above the shielding layer 414 such that the shielding layer 414 is located between the RF switch 200 and the substrate 202. An example implementation of forming the RF switch 200 is described in connection with FIGS. 7A-7J.

As indicated above, FIGS. 6A-6F are provided as examples. Other examples may differ from what is described with regard to FIGS. 6A-6F.

FIGS. 7A-7J are diagrams of an example implementation 700 of forming the RF switch 200 described herein described herein. In some implementations, the RF switch 200 may be formed in the semiconductor device 400 (e.g., above the shielding layer 414 in the interconnect region 404 of the semiconductor device 400), and/or in a semiconductor device 800 described in connection with FIGS. 8A-8C, among other examples.

In some implementations, one or more of the semiconductor processing tools 102-112 and/or the wafer/die transport tool 114 may be used to perform one or more of the semiconductor processing operations described in connection with FIGS. 7A-7J. In some implementations, one or more of the semiconductor processing operations described in connection with FIGS. 7A-7J may be performed using another semiconductor processing tool.

Turning to FIG. 7A, a dielectric layer 204 of the interconnect region 404 of the semiconductor device 400 may be formed, as described in connection with FIGS. 6A-6F.

As shown in FIG. 7B, a recess 702 may be formed in the dielectric layer 204. In some implementations, a pattern in a photoresist layer is used to form the recess 702 in the dielectric layer 204. In these implementations, a deposition tool 102 is used to form the photoresist layer on the dielectric layer 204. An exposure tool 104 is used to expos the photoresist layer to a radiation source to pattern the photoresist layer. A developer tool 106 is used to develop and remove portions of the photoresist layer to expose the pattern. An etch tool 108 is used to perform an etch operation to etch into the dielectric layer 204 to form the recess 702 in the dielectric layer 204. In some implementations, the etch operation includes the use of a plasma etch technique, a wet chemical etch technique, and/or another type of etch technique. In some implementations, a photoresist removal tool removes the remaining portions of the photoresist layer (e.g., using a chemical stripper, plasma ashing, and/or another technique).

As shown in FIG. 7C, a conductive layer 704 may be formed over and/or on the dielectric layer 204 and in the recess 702. The conductive layer 704 may be formed to a thickness such that the conductive layer 704 fully fills the recess 702. A deposition tool 102 and/or the plating tool 112 may be used to deposit the conductive layer 704 using a CVD technique, a PVD technique, an ALD technique, an electroplating technique, another deposition technique described above in connection with FIG. 1, and/or another suitable deposition technique. In some implementations, an anneal operation is performed on the RF switch 200 to reflow the conductive layer 704 to remove voids and other defects in the conductive layer 704.

As shown in FIG. 7D, a planarization tool 110 may be used to planarize the conductive layer 704 after the deposition tool 102 and/or the plating tool 112 is used to deposit the conductive layer 704. The planarization tool 110 may be used to planarize the conductive layer 704 to remove excess material of the conductive layer 704 on the dielectric layer 204 surrounding the recess 702. The remaining material of the conductive layer 704 in the recess 702 corresponds to the heater 206. Thus, the heater 206 is deposited in the recess 702.

As shown in FIG. 7E, the insulator layer 208 may be formed over and/or on the dielectric layer 204, and over and/or on the heater 206. A deposition tool 102 may be used to deposit the insulator layer 208 using a PVD technique, an ALD technique, a CVD technique, another type of deposition technique described in connection with FIG. 1, and/or another suitable deposition technique. In some implementations, a planarization tool 110 is used to planarize the insulator layer 208 after the deposition tool 102 is used to deposit the insulator layer 208.

As further shown in FIG. 7E, a layer 706 of PCM may be formed over and/or on the insulator layer 208. A deposition tool 102 may be used to deposit the layer 706 of PCM using a PVD technique, an ALD technique, a CVD technique, another type of deposition technique described in connection with FIG. 1, and/or another suitable deposition technique. In some implementations, a planarization tool 110 is used to planarize the layer 706 of PCM after the deposition tool 102 is used to deposit the layer 706 of PCM.

As further shown in FIG. 7E, a barrier layer 708 may be formed over and/or on the layer 706 of PCM. A deposition tool 102 may be used to deposit the barrier layer 708 using a PVD technique, an ALD technique, a CVD technique, another type of deposition technique described in connection with FIG. 1, and/or another suitable deposition technique. In some implementations, a planarization tool 110 is used to planarize the barrier layer 708 after the deposition tool 102 is used to deposit the barrier layer 708.

As shown in FIG. 7F, portions of the layer 706 of PCM and portions of the barrier layer 708 may be removed from the RF switch 200. The remaining portions of the layer 706 of the PCM correspond to the PCM layer 210. Accordingly, the PCM layer 210 is formed over and/or on the insulator layer 208. In some implementations, portions of the insulator layer 208 are also etched such that the width of the insulator layer 208 is approximately equal to the width of the PCM layer 210.

In some implementations, a pattern in a photoresist layer is used to etch the layer 706 of PCM and the barrier layer 708. In these implementations, a deposition tool 102 is used to form the photoresist layer on the layer 706 of PCM. An exposure tool 104 is used to expose the photoresist layer to a radiation source to pattern the photoresist layer. A developer tool 106 is used to develop and remove portions of the photoresist layer to expose the pattern. An etch tool 108 is used to perform an etch operation to etch into the layer 706 of PCM and the barrier layer 708 to remove the portions of the layer 706 of PCM and the portions of the barrier layer 708. In some implementations, the etch operation includes the use of a plasma etch technique, a wet chemical etch technique, and/or another type of etch technique. In some implementations, a photoresist removal tool removes the remaining portions of the photoresist layer (e.g., using a chemical stripper, plasma ashing, and/or another technique).

As shown in FIG. 7G, a liner 710 may be conformally formed over the PCM layer 210, over and/or on portions of the insulator layer 208, and/or over and/or on the barrier layer 708. A deposition tool 102 may be used to deposit the liner 710 using a PVD technique, an ALD technique, a CVD technique, another type of deposition technique described in connection with FIG. 1, and/or another suitable deposition technique.

As further shown in FIG. 7G, a spacer layer 712 may be formed over and/or on the liner 710. A deposition tool 102 may be used to deposit the spacer layer 712 in a PVD technique, an ALD technique, a CVD technique, another type of deposition technique described in connection with FIG. 1, and/or another suitable deposition technique. In some implementations, a planarization tool 110 is used to planarize the spacer layer 712 after the deposition tool 102 is used to deposit the spacer layer 712. The spacer layer 712 may include a silicon nitride (SiₓN_{y}) and/or another suitable spacer material.

As shown in FIG. 7H, portions of the liner 710 and portions of the spacer layer 712 are removed from the RF switch 200 such that spacers 714 are formed on sidewalls of the PCM layer 210 and on sidewalls of the barrier layer 708. In some implementations, a pattern in a photoresist layer is used to etch the liner 710 and the spacer layer 712. In these implementations, a deposition tool 102 is used to form the photoresist layer on the spacer layer 712. An exposure tool 104 is used to expose the photoresist layer to a radiation source to pattern the photoresist layer. A developer tool 106 is used to develop and remove portions of the photoresist layer to expose the pattern. An etch tool 108 is used to perform an etch operation to etch into the liner 710 and the spacer layer 712 to remove the portions of the liner 710 and the portions of the spacer layer 712 to form the spacers 714. In some implementations, the etch operation includes the use of a plasma etch technique, a wet chemical etch technique, and/or another type of etch technique. In some implementations, a photoresist removal tool removes the remaining portions of the photoresist layer (e.g., using a chemical stripper, plasma ashing, and/or another technique).

As shown in FIG. 7I, a conductive layer 716 may be formed over and/or on portions of the insulator layer 208, over the PCM layer 210, over and/or on the barrier layer 708, and/or over and/or on the spacers 714. A deposition tool 102 and/or a plating tool 112 may be used to deposit the conductive layer 716 using a CVD technique, a PVD technique, an ALD technique, an electroplating technique, another deposition technique described above in connection with FIG. 1, and/or another suitable deposition technique. In some implementations, an anneal operation may be performed on the RF switch 200 to reflow the conductive layer 716 to remove voids and other defects in the conductive layer 716. In some implementations, the conductive layer 716 is conformally deposited in that the conductive layer 716 conforms to the profile and/or contours of the layers and/or structures on which the conductive layer 716 is deposited. For example, the conductive layer 716 may be conformally deposited onto (and may conform to) the portions of the insulator layer 208, the PCM layer 210, the barrier layer 708, and/or the spacers 714.

As shown in FIG. 7J, portions of the conductive layer 716 may be removed to form the RF in electrode 212 and the RF out electrode 214. Moreover, portions of the barrier layer 708 may be removed from above the PCM layer 210 between the RF in electrode 212 and the RF out electrode 214. Remaining portions of the barrier layer 708 are located between the PCM layer 210 and the RF in electrode 212, and between the PCM layer 210 and the RF out electrode 214.

In some implementations, a pattern in a photoresist layer is used to etch the conductive layer 716 and the barrier layer 708. In these implementations, a deposition tool 102 is used to form the photoresist layer on the conductive layer 716. An exposure tool 104 is used to expose the photoresist layer to a radiation source to pattern the photoresist layer. A developer tool 106 is used to develop and remove portions of the photoresist layer to expose the pattern. An etch tool 108 is used to perform an etch operation to etch into the conductive layer 716 and into the barrier layer 708 to remove the portions of the conductive layer 716 to form the RF in electrode 214 and the RF out electrode 214, and to remove the portions of the barrier layer 708. In some implementations, the etch operation includes the use of a plasma etch technique, a wet chemical etch technique, and/or another type of etch technique. In some implementations, a photoresist removal tool removes the remaining portions of the photoresist layer (e.g., using a chemical stripper, plasma ashing, and/or another technique).

As further shown in FIG. 7J, a liner 718 is conformally formed over and/or on the RF in electrode 212, over and/or on the RF out electrode 214, and/or over and/or on portions of the PCM layer 210 between the RF in electrode 212 and the RF out electrode 214. A deposition tool 102 may be used to deposit the liner 718 using a PVD technique, an ALD technique, a CVD technique, another type of deposition technique described in connection with FIG. 1, and/or another suitable deposition technique. The liner 718 may be formed to protect the RF in electrode 212, the RF out electrode 214, and the PCM layer 210 from oxidation and other types of contamination.

As indicated above, FIGS. 7A-7J are provided as an example. Other examples may differ from what is described with regard to FIGS. 7A-7J.

FIGS. 8A-8C are diagrams of example implementations of a semiconductor device 800 described herein. The semiconductor device 800 is formed by bonding a first semiconductor wafer and a second semiconductor wafer. For example, a bonding tool may be used to perform a bonding operation to bond the first semiconductor wafer and the second semiconductor wafer using a hybrid bonding technique, a direct bonding technique, a eutectic bonding technique, and/or another bonding technique.

As shown in an example implementation of the semiconductor device 800 in FIG. 8A, the semiconductor device 800 includes a first semiconductor die 802 and a second semiconductor die 804. In the bonding operation, first semiconductor die 802 on the first semiconductor wafer are bonded with a second semiconductor die 804 on the second semiconductor wafer to form the semiconductor device 800 (e.g., a stacked semiconductor device, a wafer on wafer (WoW) device). The semiconductor device 800 may then be diced and packaged.

As shown in FIG. 8A, the first semiconductor die 802 and the second semiconductor die 804 may be bonded at a bonding interface 806 such that the first semiconductor die 802 and the second semiconductor die 804 are stacked or vertically arranged in the semiconductor device 800. The first semiconductor die 802 may include an RF front-end die, a baseband die, and/or another type of die. The second semiconductor die 804 may include an SoC die such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the second semiconductor die 804 may include a memory die, an input/output (I/O) die, a pixel sensor die, and/or another type of semiconductor die.

As further shown in FIG. 8A, the first semiconductor die 802 may include a similar combination and arrangement of layers and/or structures as the semiconductor device 400, such as a device region 402a, an interconnect region 404a, a substrate 202a, a plurality of active devices 406a, a dielectric layer 408a, a plurality of dielectric layers 204a and ESLs 410a, metallization layers 412a, an RF switch 200, and a shielding layer 414a between the RF switch 200 and the substrate 202a.

The second semiconductor die 804 may also include a similar combination and arrangement of layers and/or structures as the semiconductor device 400, such as a device region 402b, an interconnect region 404b, a substrate 202b, a plurality of active devices 406b, a dielectric layer 408b, a plurality of dielectric layers 204b and ESLs 410b, and metallization layers 412b. The second semiconductor die 804 also includes another shielding layer 414b. The shielding layer 414b is located between the RF switch 200 and the substrate 202b so that the shielding layer 414b blocks or suppresses E-field emissions and/or H-field emissions from causing a parasitic current being induced in the substrate 202b of the second semiconductor die 804. In the example implementation of the semiconductor device 800 in FIG. 8A, the shielding layer 414a is included in the interconnect region 404a of the first semiconductor die 802, and shielding layer 414b is included in the interconnect region 404b of the second semiconductor die 804. In some implementations, the shielding layer 414b is alternatively included in the bonding region 808b of the second semiconductor die 804.

As further shown in FIG. 8A, first semiconductor die 802 may include a bonding region 808a, and the second semiconductor die 804 may include a bonding region 808b. The bonding region 808a includes a plurality of dielectric layers, such as dielectric layers 810a-822a, and a plurality of metallization layers, such as metallization layers 824a-830a, included in the dielectric layers 810a-822a. The bonding region 808b includes a plurality of dielectric layers, such as dielectric layers 810b-822b, and a plurality of metallization layers, such as metallization layers 824b-830b, included in the dielectric layers 810b-822b. The dielectric layers may include nitride layers, extreme low dielectric constant (ELK) dielectric layers Examples of materials included in the dielectric layers include a silicon nitride (SiₓN_{y} such as Si₃N₄), a silicon oxide (SiOₓ such as SiO₂), silicon carbide (SiC), a silicon oxynitride (SiON), a silicon carbon nitride (SiCN), a silicon oxycarbonitride (SiOCN), carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples. The metallization layers may include vias, interconnects, conductive columns, plugs, contacts, trenches, pads, and/or another type of conductive structure. The metallization layers may include one or more electrically conductive metals, such as copper (Cu), tungsten (W), cobalt (Co), ruthenium (Ru), titanium (Ti), aluminum (Al), gold (Au), and/or a combination thereof, among other examples of electrically conductive materials.

At the bonding interface 806, the dielectric layer 822a and the dielectric layer 822b are bonded by a dielectric-to-dielectric bond. The metallization layers 830a and the metallization layers 830b are bonded by a metal-to-metal bond. The combination of the dielectric-to-dielectric bond and the metal-to-metal bond is referred to as a hybrid bond.

In this way, the semiconductor device 800 includes a first semiconductor die 802 and a second semiconductor die 804. The first semiconductor die 802 includes a substrate 202a and an interconnect region 404a below the substrate 202a. The first semiconductor die 802 includes an RF switch 200 in the interconnect region 404a below the substrate 202a, and a shielding layer 414a in the interconnect region 404a between the substrate 202a and the RF switch 200. The first semiconductor die 802 includes a bonding region 808a below the interconnect region 404a. The second semiconductor die 804 includes a substrate 202b, an interconnect region 404b above the substrate 202b, a bonding region 808b above the interconnect region 404b, and a shielding layer 414b in the interconnect region 404b. The first semiconductor die 802 and the second semiconductor die 804 are bonded at a bonding interface 806 between the bonding region 808a and the bonding region 808b.

FIG. 8B illustrates another example implementation of the semiconductor device 800 in which the shielding layer 414b is included in the first semiconductor die 802 instead of in the second semiconductor die 804. In the example implementation of the semiconductor device 800 in FIG. 8B, the shielding layer 414b is included the bonding region 808a of the first semiconductor die 802 such that the shielding layer 414b is between the RF switch 200 and the substrate 202b of the second semiconductor die 804. Including the shielding layer 414b in the first semiconductor die 802 reduced manufacturing complexity for the second semiconductor die 804.

FIG. 8C illustrates another example implementation of the semiconductor device 800 in which the shielding layer 414b is included in the first semiconductor die 802 instead of in the second semiconductor die 804. In the example implementation of the semiconductor device 800 in FIG. 8C, the shielding layer 414b is included the interconnect region 404a of the first semiconductor die 802 such that the shielding layer 414b is between the RF switch 200 and the substrate 202b of the second semiconductor die 804.

As indicated above, FIGS. 8A-8C are provided as examples. Other examples may differ from what is described with regard to FIGS. 8A-8C.

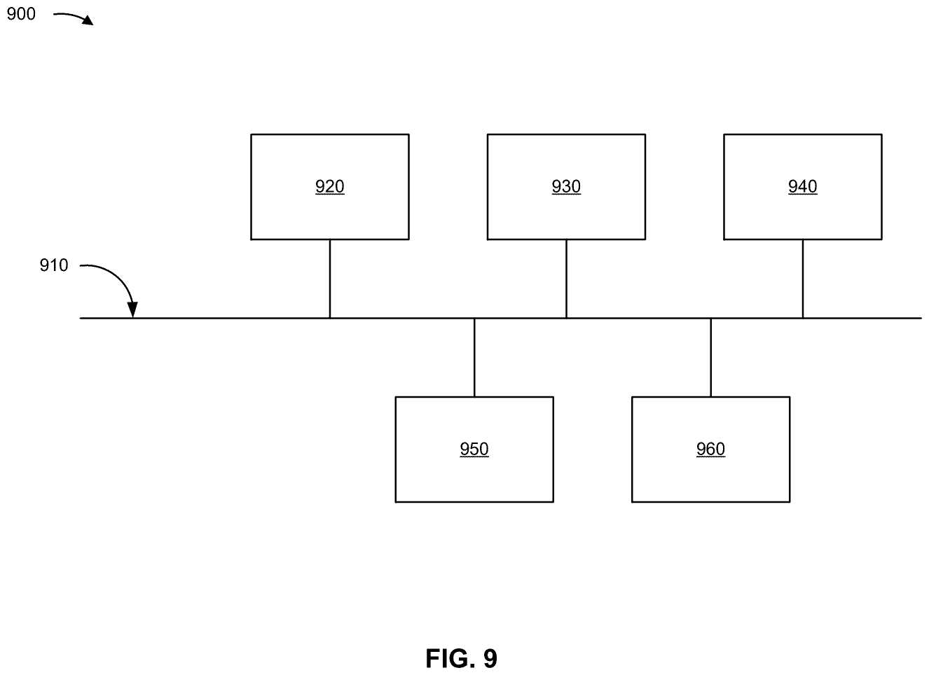

FIG. 9 is a diagram of example components of a device 900 described herein. In some implementations, one or more of the semiconductor processing tools 102-112 and/or the wafer/die transport tool 114 may include one or more devices 900 and/or one or more components of the device 900. As shown in FIG. 9, the device 900 may include a bus 910, a processor 920, a memory 930, an input component 940, an output component 950, and/or a communication component 960.

The bus 910 may include one or more components that enable wired and/or wireless communication among the components of the device 900. The bus 910 may couple together two or more components of FIG. 9, such as via operative coupling, communicative coupling, electronic coupling, and/or electric coupling. For example, the bus 910 may include an electrical connection (e.g., a wire, a trace, and/or a lead) and/or a wireless bus. The processor 920 may include a central processing unit, a graphics processing unit, a microprocessor, a controller, a microcontroller, a digital signal processor, a field-programmable gate array, an application-specific integrated circuit, and/or another type of processing component. The processor 920 may be implemented in hardware, firmware, or a combination of hardware and software. In some implementations, the processor 920 may include one or more processors capable of being programmed to perform one or more operations or processes described elsewhere herein.

The memory 930 may include volatile and/or nonvolatile memory. For example, the memory 930 may include random access memory (RAM), read only memory (ROM), a hard disk drive, and/or another type of memory (e.g., a flash memory, a magnetic memory, and/or an optical memory). The memory 930 may include internal memory (e.g., RAM, ROM, or a hard disk drive) and/or removable memory (e.g., removable via a universal serial bus connection). The memory 930 may be a non-transitory computer-readable medium. The memory 930 may store information, one or more instructions, and/or software (e.g., one or more software applications) related to the operation of the device 900. In some implementations, the memory 930 may include one or more memories that are coupled (e.g., communicatively coupled) to one or more processors (e.g., processor 920), such as via the bus 910. Communicative coupling between a processor 920 and a memory 930 may enable the processor 920 to read and/or process information stored in the memory 930 and/or to store information in the memory 930.

The input component 940 may enable the device 900 to receive input, such as user input and/or sensed input. For example, the input component 940 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 950 may enable the device 900 to provide output, such as via a display, a speaker, and/or a light-emitting diode. The communication component 960 may enable the device 900 to communicate with other devices via a wired connection and/or a wireless connection. For example, the communication component 960 may include a receiver, a transmitter, a transceiver, a modem, a network interface card, and/or an antenna.

The device 900 may perform one or more operations or processes described herein. For example, a non-transitory computer-readable medium (e.g., memory 930) may store a set of instructions (e.g., one or more instructions or code) for execution by the processor 920. The processor 920 may execute the set of instructions to perform one or more operations or processes described herein. In some implementations, execution of the set of instructions, by one or more processors 920, causes the one or more processors 920 and/or the device 900 to perform one or more operations or processes described herein. In some implementations, hardwired circuitry may be used instead of or in combination with the instructions to perform one or more operations or processes described herein. Additionally, or alternatively, the processor 920 may be configured to perform one or more operations or processes described herein. Thus, implementations described herein are not limited to any specific combination of hardware circuitry and software.

The number and arrangement of components shown in FIG. 9 are provided as an example. The device 900 may include additional components, fewer components, different components, or differently arranged components than those shown in FIG. 9. Additionally, or alternatively, a set of components (e.g., one or more components) of the device 900 may perform one or more functions described as being performed by another set of components of the device 900.

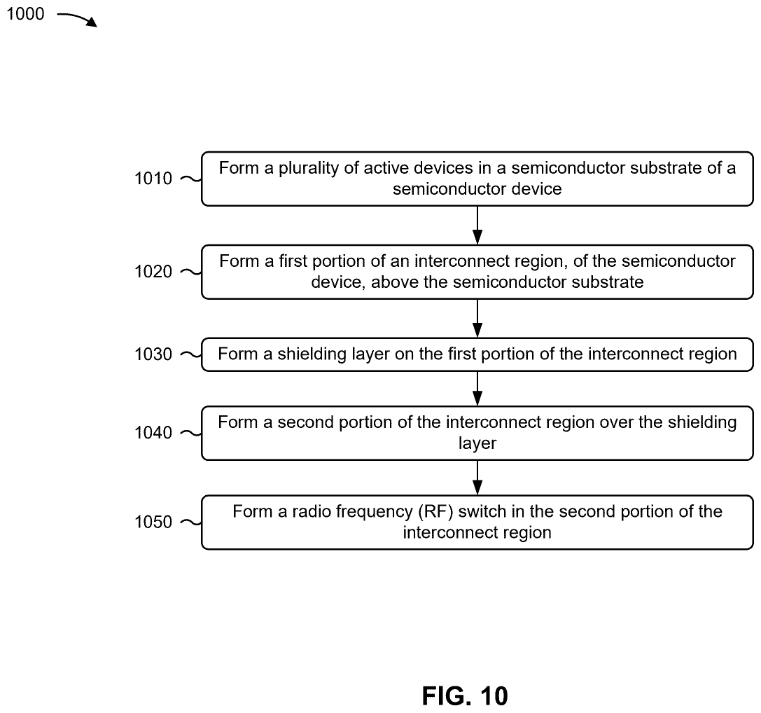

FIG. 10 is a flowchart of an example process 1000 associated with forming a semiconductor device described herein. In some implementations, one or more process blocks of FIG. 10 are performed using one or more semiconductor processing tools (e.g., one or more of the semiconductor processing tools 102-112). Additionally, or alternatively, one or more process blocks of FIG. 10 may be performed using one or more components of device 900, such as processor 920, memory 930, input component 940, output component 950, and/or communication component 960.

As shown in FIG. 10, process 1000 may include forming a plurality of active devices in a semiconductor substrate of a semiconductor device (block 1010). For example, one or more of the semiconductor processing tools 102-112 may be used to form a plurality of active devices (e.g., the active devices 406, the active devices 406a) in a semiconductor substrate (e.g., the substrate 202, the substrate 202a) of a semiconductor device (e.g., the semiconductor device 400, the semiconductor device 800), as described herein.

As further shown in FIG. 10, process 1000 may include forming a first portion of an interconnect region, of the semiconductor device, above the semiconductor substrate (block 1020). For example, one or more of the semiconductor processing tools 102-112 may be used to form a first portion of an interconnect region (e.g., the interconnect region 404, the interconnect region 404a), of the semiconductor device, above the semiconductor substrate, as described herein.

As further shown in FIG. 10, process 1000 may include forming a shielding layer on the first portion of the interconnect region (block 1030). For example, one or more of the semiconductor processing tools 102-112 may be used to form a shielding layer (e.g., the shielding layer 414, the shielding layer 414a) on the first portion of the interconnect region, as described herein.

As further shown in FIG. 10, process 1000 may include forming a second portion of the interconnect region over the shielding layer (block 1040). For example, one or more of the semiconductor processing tools 102-112 may be used to form a second portion of the interconnect region over the shielding layer, as described herein.

As further shown in FIG. 10, process 1000 may include forming an RF switch in the second portion of the interconnect region (block 1050). For example, one or more of the semiconductor processing tools 102-112 may be used to form an RF switch 200 in the second portion of the interconnect region, as described herein.

Process 1000 may include additional implementations, such as any single implementation or any combination of implementations described below and/or in connection with one or more other processes described elsewhere herein.

In a first implementation, forming the shielding layer includes depositing the shielding layer, and removing portions of the shielding layer such that gaps are included between remaining portions (e.g., shielding segments 418) of the shielding layer.

In a second implementation, alone or in combination with the first implementation, forming the shielding layer includes forming a first shielding layer on the first portion of the interconnect region, and the process 1000 includes forming a second shielding layer 414b above the RF switch 200.

In a third implementation, alone or in combination with one or more of the first and second implementations, forming the shielding layer includes forming a mixture that includes an iron powder and an epoxy precursor, depositing a layer of the mixture on the first portion of the interconnect region, and performing a baking operation on the layer of the mixture to form the shielding layer.

In a fourth implementation, alone or in combination with one or more of the first through third implementations, the semiconductor substrate, the interconnect region, the shielding layer, and the RF switch 200 are included in a first semiconductor die 802 of the semiconductor device, and the process 1000 includes bonding the first semiconductor die 802 and a second semiconductor die 804 after forming the RF switch 200, where the second semiconductor die 804 includes another shielding layer 414b.

In a fifth implementation, alone or in combination with one or more of the first through fourth implementations, forming the shielding layer includes forming the shielding layer to a thickness (e.g., the dimension D1) that is included in a range of approximately 200 nanometers to approximately 20 microns.

In a sixth implementation, alone or in combination with one or more of the first through fifth implementations, the shielding layer includes at least one of aluminum (Al), tantalum nitride (TaN), titanium nitride (TiN), copper (Cu), polysilicon, tungsten (W), or cobalt (Co).

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, a semiconductor device includes an RF switch. A shielding layer is included between the RF switch and the semiconductor substrate of the semiconductor device. The shielding layer suppresses E-field emissions and/or H-field emissions generated by the RF switch, which prevents, minimizes, and/or otherwise reduces the likelihood of the E-field emissions and/or the H-field emissions causing a parasitic current to be induced in the semiconductor substrate. In this way, the shielding layer described herein reduces, minimizes, and/or prevents harmonic distortion in the operation of the RF switch. This enables the RF switch to maintain linear operation, which enables more accurate and faster switching for the RF circuit (e.g., relative to if the shielding layer were omitted from the semiconductor device). The more accurate and faster switching of the RF switch reduces the error rate and/or reduces the likelihood of corruption of data encoded in the output signals of the RF switch, and/or reduces the likelihood that harmonic distortion renders the RF switch inoperable, among other examples.

As described in greater detail above, some implementations described herein provide a semiconductor device. The semiconductor device includes a semiconductor substrate. The semiconductor device includes an RF switch above the semiconductor substrate. The semiconductor device includes a shielding layer between the semiconductor substrate and the RF switch.

As described in greater detail above, some implementations described herein provide a method. The method includes forming a plurality of active devices in a semiconductor substrate of a semiconductor device. The method includes forming a first portion of an interconnect region, of the semiconductor device, above the semiconductor substrate. The method includes forming a shielding layer on the first portion of the interconnect region. The method includes forming a second portion of the interconnect region over the shielding layer. The method includes forming an RF switch in the second portion of the interconnect region.

As described in greater detail above, some implementations described herein provide a semiconductor device. The semiconductor device includes a first semiconductor die that includes a first semiconductor substrate, a first interconnect region below the first semiconductor substrate, an RF switch included in the first interconnect region below the first semiconductor substrate, a shielding layer included in the first interconnect region, where the shielding layer is located between the first semiconductor substrate and the RF switch, and a first bonding region below the first interconnect region. The semiconductor device includes a second semiconductor die that includes a second semiconductor substrate, a second interconnect region above the second semiconductor substrate, and a second bonding region above the second interconnect region, where the first semiconductor die and the second semiconductor die are bonded at a bonding interface between the first bonding region and the second bonding region.

As used herein, “satisfying a threshold” may, depending on the context, refer to a value being greater than the threshold, greater than or equal to the threshold, less than the threshold, less than or equal to the threshold, equal to the threshold, and/or not equal to the threshold, depending on the context.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor substrate;
a radio frequency (RF) switch above the semiconductor substrate; and
a shielding layer between the semiconductor substrate and the RF switch.

2. The semiconductor device of claim 1, wherein the shielding layer comprises a continuous layer of material between the semiconductor substrate and the RF switch.

3. The semiconductor device of claim 1, wherein the shielding layer comprises a plurality of discontinuous segments of material between the semiconductor substrate and the RF switch.

4. The semiconductor device of claim 1, wherein the shielding layer comprises an iron-containing epoxy material.

5. The semiconductor device of claim 1, wherein the shielding layer has an electrical conductivity that is greater than approximately 1×10⁶ siemens per meter (S/m).

6. The semiconductor device of claim 1, wherein the shielding layer is electrically coupled to an electrical grounding path of the semiconductor device.

7. The semiconductor device of claim 1, wherein the RF switch and the shielding layer are both included in an interconnect region of the semiconductor device.

8. A method, comprising:
forming a plurality of active devices in a semiconductor substrate of a semiconductor device;
forming a first portion of an interconnect region, of the semiconductor device, above the semiconductor substrate;
forming a shielding layer on the first portion of the interconnect region;
forming a second portion of the interconnect region over the shielding layer; and
forming a radio frequency (RF) switch in the second portion of the interconnect region.

9. The method of claim 8, wherein forming the shielding layer comprises:
depositing the shielding layer; and
removing portions of the shielding layer such that gaps are included between remaining portions of the shielding layer.

10. The method of claim 8, wherein forming the shielding layer comprises:
forming a first shielding layer on the first portion of the interconnect region; and
wherein the method further comprises:
forming a second shielding layer above the RF switch.

11. The method of claim 8, wherein forming the shielding layer comprises:
forming a mixture that includes an iron powder and an epoxy precursor;
depositing a layer of the mixture on the first portion of the interconnect region; and
performing a baking operation on the layer of the mixture to form the shielding layer.

12. The method of claim 8, wherein the semiconductor substrate, the interconnect region, the shielding layer, and the RF switch are included in a first semiconductor die of the semiconductor device; and
wherein the method further comprises:
bonding the first semiconductor die and a second semiconductor die after forming the RF switch,
wherein the second semiconductor die includes another shielding layer.

13. The method of claim 8, wherein forming the shielding layer comprises:
forming the shielding layer to a thickness that is included in a range of approximately 200 nanometers to approximately 20 microns.

14. The method of claim 8, wherein the shielding layer comprises at least one of:
aluminum (Al),
tantalum nitride (TaN),
titanium nitride (TiN),
copper (Cu),
polysilicon,
tungsten (W), or
cobalt (Co).

15. A semiconductor device, comprising:
a first semiconductor die, comprising:
a first semiconductor substrate;
a first interconnect region below the first semiconductor substrate;
a radio frequency (RF) switch included in the first interconnect region below the first semiconductor substrate;
a shielding layer included in the first interconnect region,
wherein the shielding layer is located between the first semiconductor substrate and the RF switch; and
a first bonding region below the first interconnect region;
a second semiconductor die, comprising:
a second semiconductor substrate;
a second interconnect region above the second semiconductor substrate; and
a second bonding region above the second interconnect region,
wherein the first semiconductor die and the second semiconductor die are bonded at a bonding interface between the first bonding region and the second bonding region.

16. The semiconductor device of claim 15, wherein the shielding layer is a first shielding layer; and
wherein the second semiconductor die further comprises:
a second shielding layer located between the RF switch and the second semiconductor substrate.

17. The semiconductor device of claim 15, wherein the shielding layer is a first shielding layer; and
wherein the first semiconductor die further comprises:
a second shielding layer located between the RF switch and the bonding interface.

18. The semiconductor device of claim 17, wherein the second shielding layer is located in the first interconnect region of the first semiconductor die.

19. The semiconductor device of claim 17, wherein the second shielding layer is located in the first bonding region of the first semiconductor die.

20. The semiconductor device of claim 15, wherein the shielding layer comprises at least one of:
a nickel-containing material,
a cobalt-containing material, or
an iron-containing material.
